(19) United States
(12) Patent Application Publication
(10) Pub. No.: US 2025/0300151 A1
(43) Pub. Date: Sep. 25, 2025

(54) SEMICONDUCTOR DEVICE, SEMICONDUCTOR MODULE, AND METHOD FOR MANUFACTURING SEMICONDUCTOR DEVICE

(71) Applicant: ROHM CO., LTD., Kyoto-shi (JP)

(72) Inventor: Isamu NISHIMURA, Kyoto-shi (JP)

(73) Assignee: ROHM CO., LTD., Kyoto-shi (JP)

(21) Appl. No.: 19/230,586

(22) Filed: Jun. 6, 2025

Related U.S. Application Data
(63) Continuation of application No. PCT/JP2023/042037, filed on Nov. 22, 2023.

(30) Foreign Application Priority Data
Dec. 14, 2022 (JP) 2022-199267

(51) Int. Cl. H01L 25/18; H01L 23/31; H01L 25/00; H10D 30/47; H10D 62/85

(52) U.S. Cl. CPC H01L 25/18; H01L 23/3107; H01L 25/50; H10D 30/471; H10D 62/8503

(57) ABSTRACT

A semiconductor device includes multiple GaN units arranged separately from each other in a first direction in a first encapsulation resin. The GaN unit includes a substrate, a GaN transistor arranged at a substrate front surface side of the substrate, and a post arranged on a source pad, a drain pad, and a gate pad of the GaN transistor and exposed from the first encapsulation resin. The post includes a source post formed on the source pad in one of two adjacent ones of the GaN units in the first direction, and a drain post formed on the drain pad in the other one of the two adjacent ones of the GaN units in the first direction. The semiconductor device includes an interconnect layer arranged on an encapsulation front surface and electrically connects the source post and the drain post.

### CROSS-REFERENCE TO RELATED APPLICATIONS

This application is a continuation of, and claims the benefit of priority from International Application No. PCT/JP2023/042037, filed on Nov. 22, 2023, which claims the benefit of priority from Japanese Patent Application No. 2022-199267, filed on Dec. 14, 2022, the entire contents of each of which are incorporated herein by reference.

### BACKGROUND

The present disclosure relates to a semiconductor device, a semiconductor module, and a method for manufacturing a semiconductor device.

Japanese Laid-Open Patent Publication No. 2018-182330 describes an example of a semiconductor device that includes a substrate on which a conductive layer is formed, multiple switching elements mounted on the substrate, and wires electrically connecting the switching elements to the conductive layer.

### BRIEF DESCRIPTION OF THE DRAWINGS

FIG. 1 is a perspective view of an exemplary semiconductor device according to an embodiment.

FIG. 2 is an exemplary schematic plan view of an internal structure of the semiconductor device shown in FIG. 1.

FIG. 3 is a schematic plan view of one of GaN units in the semiconductor device shown in FIG. 1.

FIG. 4 is a bottom view of the semiconductor device shown in FIG. 1.

FIG. 5 is a schematic cross-sectional view of a GaN transistor of the semiconductor device shown in FIG. 1.

FIG. 6 is a schematic plan view of the GaN transistor shown in FIG. 5.

FIG. 7 is a schematic cross-sectional view of the semiconductor device taken along line F7-F7 in FIG. 2.

FIG. 8 is a schematic cross-sectional view of the semiconductor device taken along line F8-F8 in FIG. 2.

FIG. 9 is a circuit diagram of the semiconductor device shown in FIG. 1.

FIG. 10 is a schematic plan view showing an internal structure of an exemplary semiconductor module according to an embodiment.

FIG. 11 is an enlarged view of the semiconductor module shown in FIG. 10 including a semiconductor device.

FIG. 12 is a bottom view of the semiconductor module shown in FIG. 10.

FIG. 13 is a schematic cross-sectional view of the semiconductor module taken along line F13-F13 in FIG. 10.

FIG. 14 is a circuit diagram showing a portion of the circuit configuration of the semiconductor module shown in FIG. 10.

FIG. 15 is a schematic cross-sectional diagram illustrating an exemplary manufacturing step of the semiconductor device shown in FIG. 1.

FIG. 16 is a schematic cross-sectional diagram illustrating an exemplary manufacturing step following the step of FIG. 15.

FIG. 17 is a schematic cross-sectional diagram illustrating an exemplary manufacturing step following the step of FIG. 16.

FIG. 18 is a schematic cross-sectional diagram illustrating an exemplary manufacturing step following the step of FIG. 17.

FIG. 19 is a schematic cross-sectional diagram illustrating an exemplary manufacturing step following the step of FIG. 18.

FIG. 20 is a schematic cross-sectional diagram illustrating an exemplary manufacturing step following the step of FIG. 19.

FIG. 21 is a schematic cross-sectional diagram illustrating an exemplary manufacturing step following the step of FIG. 20.

FIG. 22 is a schematic cross-sectional diagram illustrating an exemplary manufacturing step following the step of FIG. 21.

FIG. 23 is a schematic cross-sectional diagram illustrating an exemplary manufacturing step following the step of FIG. 22.

FIG. 24 is a schematic cross-sectional diagram illustrating an exemplary manufacturing step following the step of FIG. 23.

FIG. 25 is a schematic cross-sectional diagram illustrating an exemplary manufacturing step following the step of FIG. 24.

FIG. 26 is a schematic cross-sectional diagram illustrating an exemplary manufacturing step following the step of FIG. 25.

FIG. 27 is a schematic cross-sectional diagram illustrating an exemplary manufacturing step following the step of FIG. 26.

FIG. 28 is a schematic cross-sectional diagram illustrating an exemplary manufacturing step following the step of FIG. 27.

FIG. 29 is a schematic cross-sectional diagram illustrating an exemplary manufacturing step following the step of FIG. 28.

FIG. 30 is a schematic cross-sectional diagram illustrating an exemplary manufacturing step following the step of FIG. 29.

FIG. 31 is a schematic cross-sectional diagram illustrating an exemplary manufacturing step following the step of FIG. 30.

FIG. 32 is a schematic cross-sectional diagram illustrating an exemplary manufacturing step following the step of FIG. 31.

FIG. 33 is a schematic cross-sectional diagram illustrating an exemplary manufacturing step following the step of FIG. 32.

FIG. 34 is a schematic cross-sectional diagram illustrating an exemplary manufacturing step following the step of FIG. 33.

FIG. 35 is a schematic cross-sectional diagram illustrating an exemplary manufacturing step following the step of FIG. 34.

FIG. 36 is a schematic cross-sectional diagram illustrating an exemplary manufacturing step following the step of FIG. 35.

FIG. 37 is a schematic cross-sectional diagram illustrating an exemplary manufacturing step following the step of FIG. 36.

FIG. 38 is a schematic cross-sectional diagram illustrating an exemplary manufacturing step following the step of FIG. 37.

FIG. 39 is a schematic cross-sectional diagram illustrating an exemplary manufacturing step following the step of FIG. 38.

FIG. 40 is a schematic cross-sectional diagram illustrating an exemplary manufacturing step following the step of FIG. 39.

FIG. 41 is a schematic cross-sectional diagram illustrating an exemplary manufacturing step following the step of FIG. 40.

FIG. 42 is a schematic plan diagram illustrating an exemplary manufacturing step following the step of FIG. 41.

FIG. 43 is a perspective view of a semiconductor device according to a modified example.

FIG. 44 is an exemplary schematic plan view of an internal structure of the semiconductor device shown in FIG. 43.

FIG. 45 is a bottom view of the semiconductor device shown in FIG. 43.

FIG. 46 is a schematic cross-sectional view of a GaN transistor in a semiconductor device according to a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

### Overall Structure of Semiconductor Device

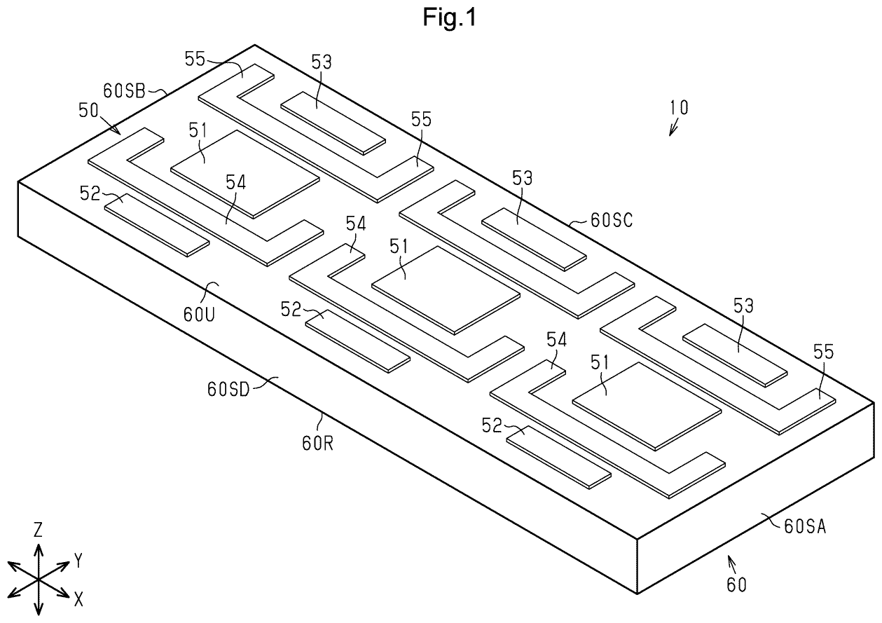

FIG. 1 is a perspective view showing the exterior of a semiconductor device 10 according to an embodiment.

As shown in FIG. 1, the semiconductor device 10 includes a first encapsulation resin 60 having the form of a rectangular plate and an external wiring layer 50 exposed from the first encapsulation resin 60. The thickness-wise direction of the first encapsulation resin 60 is referred to as a “Z-direction.” Two directions orthogonal to each other and the Z-direction are referred to as an “X-direction” and a “Y-direction.” In the present specification, “plan view” means that the semiconductor device 10 is viewed from the thickness-wise direction (Z-direction) of the first encapsulation resin 60. The first encapsulation resin 60 is rectangular in plan view so that the long sides extend in the X-direction and the short sides extend in the Y-direction.

The first encapsulation resin 60 includes an encapsulation front surface 60U and an encapsulation back surface 60R facing opposite directions in the Z-direction, and first to fourth encapsulation side surfaces 60SA to 60SD intersecting with the encapsulation front surface 60U and the encapsulation back surface 60R. In the example shown in FIG. 1, the encapsulation front surface 60U and the encapsulation back surface 60R are each flat and orthogonal to the Z-direction. In an example, the first to fourth encapsulation side surfaces 60SA to 60SD are each flat and orthogonal to the encapsulation front surface 60U and the encapsulation back surface 60R. The first encapsulation side surface 60SA and the second encapsulation side surface 60SB define two end surfaces of the first encapsulation resin 60 in the X-direction. The third encapsulation side surface 60SC and the fourth encapsulation side surface 60SD define two end surfaces of the first encapsulation resin 60 in the Y-direction.

The external wiring layer 50 is exposed from the encapsulation front surface 60U. The external wiring layer 50 is arranged on the encapsulation front surface 60U. The external wiring layer 50 includes interconnect layers 51, drain wiring layers 52, source wiring layers 53, first gate wiring layers 54, and second gate wiring layers 55. In the example shown in FIG. 1, three interconnect layers 51, three drain wiring layers 52, three source wiring layers 53, three first gate wiring layers 54, and three second gate wiring layers 55 are arranged. The interconnect layers 51, the drain wiring layers 52, the source wiring layers 53, the first gate wiring layers 54, and the second gate wiring layers 55 are spaced apart from each other in a direction orthogonal to the thickness-wise direction of the first encapsulation resin 60. In the example shown in FIG. 1, three sets of the interconnect layer 51, the drain wiring layer 52, the source wiring layer 53, the first gate wiring layer 54, and the second gate wiring layer 55 that are spaced apart from each other in the Y-direction are arranged to be spaced apart from each other in the X-direction. In plan view, the drain wiring layer 52, the first gate wiring layer 54, the interconnect layer 51, the second gate wiring layer 55, and the source wiring layer 53 are arranged in this order in a direction from the fourth encapsulation side surface 60SD toward the third encapsulation side surface 60SC.

In plan view, the interconnect layers 51 are arranged in the center of the first encapsulation resin 60 in the Y-direction. The interconnect layers 51 are aligned with each other in the Y-direction and spaced apart from each other in the X-direction. Each interconnect layer 51 is rectangular in plan view.

In plan view, the drain wiring layers 52 are arranged at an end of the first encapsulation resin 60 located toward the fourth encapsulation side surface 60SD in the Y-direction. The drain wiring layers 52 are aligned with each other in the Y-direction and spaced apart from each other in the X-direction. Each drain wiring layer 52 is strip-shaped and extends in the X-direction in plan view.

In plan view, the source wiring layers 53 are disposed at an end portion of the first encapsulation resin 60 closer to the third encapsulation side surface 60SC in the Y-direction. The source wiring layers 53 are aligned with each other in the Y-direction and spaced apart from each other in the X-direction. Each source wiring layer 53 is strip-shaped and extends in the X-direction in plan view.

In plan view, the first gate wiring layers 54 are arranged closer to the third encapsulation side surface 60SC, in the Y-direction, than the drain wiring layers 52 are. The first gate wiring layers 54 are aligned with each other in the Y-direction and spaced apart from each other in the X-direction. Each first gate wiring layer 54 is substantially U-shaped and is open toward the third encapsulation side surface 60SC in plan view. The first gate wiring layers 54 are arranged closer to the fourth encapsulation side surface 60SD, in the Y-direction, than the interconnect layers 51 are. Each interconnect layer 51 is partially received in the recess of a corresponding one of the first gate wiring layers 54 in plan view.

In plan view, the second gate wiring layers 55 are arranged closer to the third encapsulation side surface 60SC, in the Y-direction, than the interconnect layers 51 are. The second gate wiring layers 55 are aligned with each other in the Y-direction and spaced apart from each other in the X-direction. Each second gate wiring layer 55 is substantially U-shaped and surrounds the source wiring layer 53 located adjacent in the Y-direction in plan view. In plan view, the second gate wiring layer 55 is identical in shape to the first gate wiring layer 54. Each source wiring layer 53 is partially received in the recess of a corresponding one of the second gate wiring layers 55 in plan view.

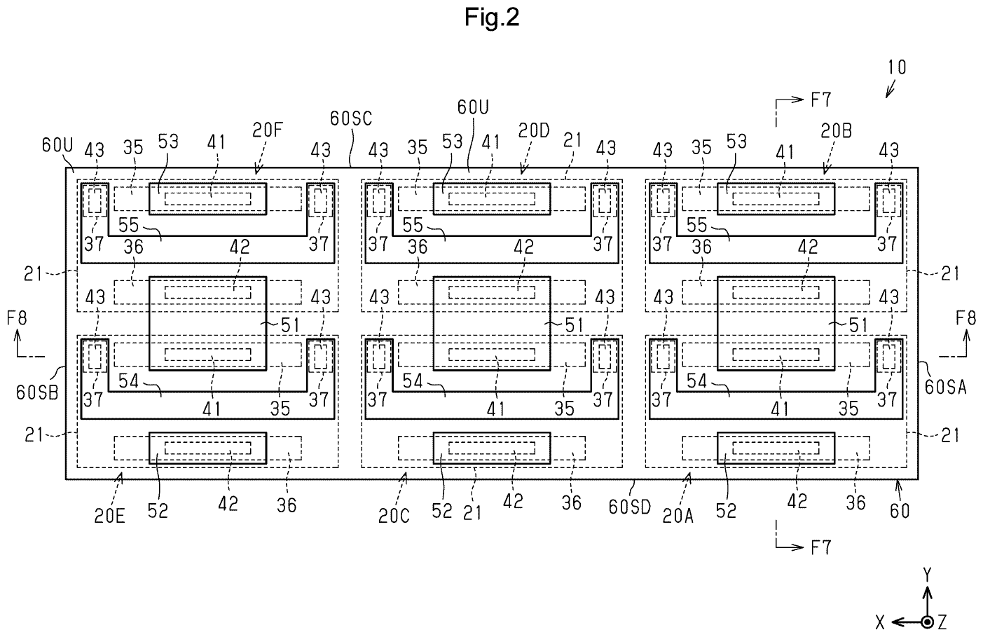

FIG. 2 is a schematic plan view of the semiconductor device 10 shown in FIG. 1. In FIG. 2, broken lines indicate a schematic internal structure of the semiconductor device 10.

As shown in FIG. 2, the semiconductor device 10 includes multiple (in the present embodiment, six) gallium nitride (GaN) units 20A to 20F. The GaN units 20A to 20F are arranged in the first encapsulation resin 60 separately from each other in a first direction (Y-direction) orthogonal to the Z-direction. In the example shown in FIG. 2, three sets of two GaN units that are located adjacent to each other in the first direction (Y-direction) are spaced apart from each other in a second direction (X-direction). More specifically, a set of the GaN units 20A and 20B located adjacent to each other in the Y-direction, a set of the GaN units 20C and 20D located adjacent to each other in the Y-direction, and a set of the GaN units 20E and 20F located adjacent to each other in the Y-direction are spaced apart from each other in the X-direction. The second direction refers to a direction orthogonal to the thickness-wise direction (Z-direction) of the first encapsulation resin 60 and to the first direction (Y-direction). In the present embodiment, the second direction is the X-direction.

In plan view, the GaN units 20A, 20C, and 20E are aligned with each other in the Y-direction and spaced apart from each other in the X-direction. In plan view, the GaN units 20B, 20D, and 20F are aligned with each other in the Y-direction and spaced apart from each other in the X-direction. In plan view, the GaN units 20A, 20C, and 20E are arranged closer to the fourth encapsulation side surface 60SD than the GaN units 20B, 20D, and 20F are. In plan view, the GaN unit 20A is arranged closer to the first encapsulation side surface 60SA than the GaN units 20C and 20E are. The GaN unit 20E is arranged closer to the second encapsulation side surface 60SB than the GaN units 20A and 20C are. The GaN unit 20C is arranged between the GaN unit 20A and the GaN unit 20E in the X-direction. In plan view, the GaN unit 20B is arranged closer to the first encapsulation side surface 60SA than the GaN units 20D and 20F are. The GaN unit 20F is arranged closer to the second encapsulation side surface 60SB than the GaN units 20B and 20D are. The GaN unit 20D is arranged between the GaN unit 20B and the GaN unit 20F in the X-direction.

The planar structure of the GaN units 20A to 20F will now be described.

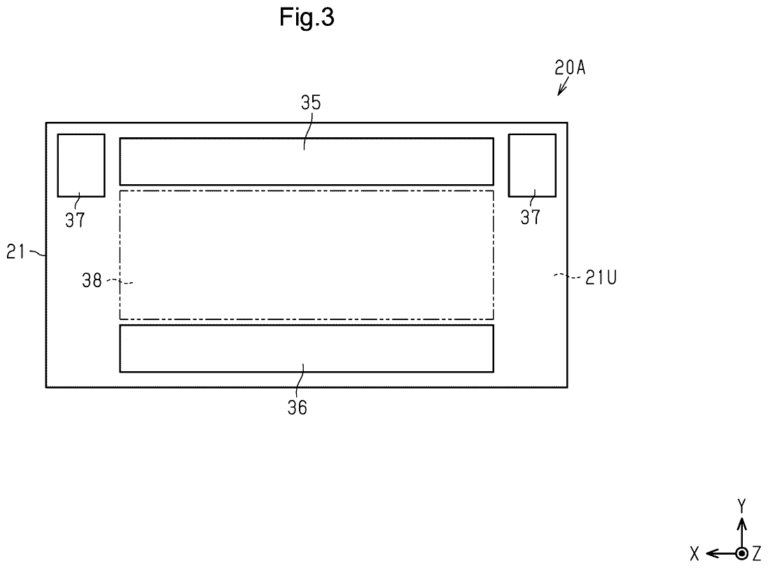

FIG. 3 is a schematic plan view showing the planar structure of the GaN unit 20A. The GaN units 20B to 20F have the same structure as the GaN unit 20A and thus will not be described in detail.

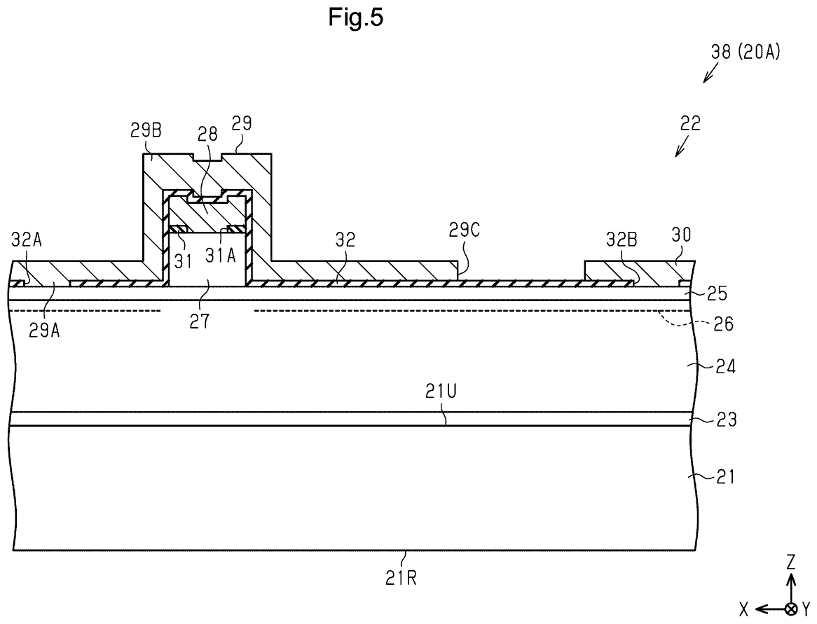

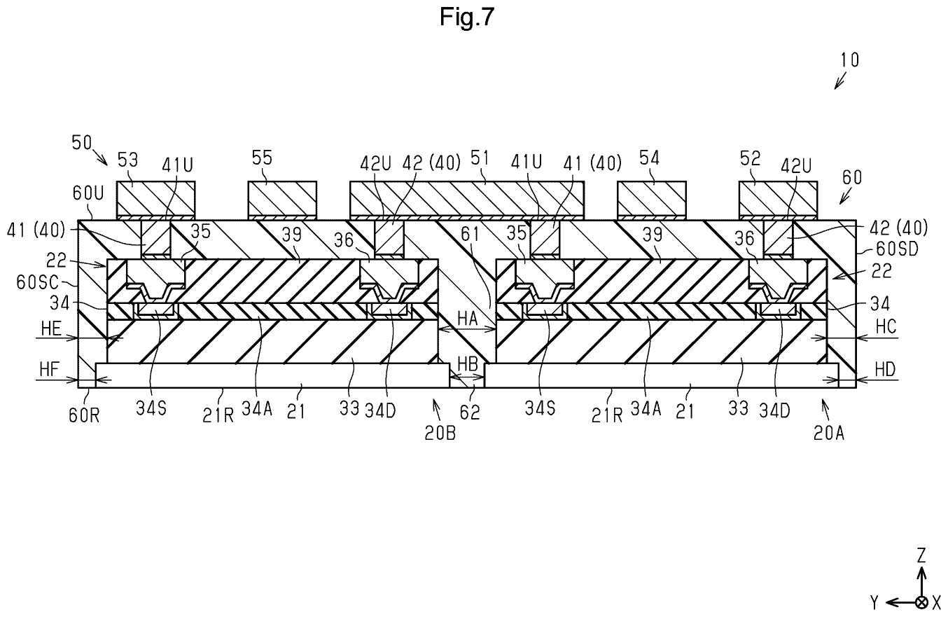

As shown in FIG. 3, the GaN unit 20A includes a substrate 21. The substrate 21 has the form of a rectangular plate having a thickness in the Z-direction. The substrate 21 includes a substrate front surface 21U and a substrate back surface 21R (refer to FIG. 5) facing opposite directions in the Z-direction. The substrate front surface 21U faces the same direction as the encapsulation front surface 60U (refer to FIG. 7) of the first encapsulation resin 60. The substrate back surface 21R faces the same direction as the encapsulation back surface 60R (refer to FIG. 7).

The substrate 21 may be formed from silicon (Si), silicon carbide (SiC), gallium nitride (GaN), sapphire, or another substrate material. The substrate 21 may be a semiconductor substrate. In an example, the substrate 21 may be a Si substrate. The substrate 21 may have a thickness, for example, in a range of 200 μm to 1500 μm, inclusive.

The GaN unit 20A includes a source pad 35, a drain pad 36, and a gate pad 37 arranged on the substrate 21.

The drain pad 36 is arranged at an end of the GaN unit 20A located toward the fourth encapsulation side surface 60SD of the first encapsulation resin 60. In plan view, the drain pad 36 is strip-shaped and extends in the X-direction.

As shown in FIG. 2, the drain pad 36 is arranged to overlap the drain wiring layer 52 in plan view. In the example shown in FIG. 2, the drain pad 36 is greater than the drain wiring layer 52 in length in the X-direction. The drain pad 36 is electrically connected to the drain wiring layer 52.

As shown in FIG. 3, the source pad 35 is spaced apart from the drain pad 36 and arranged closer to the third encapsulation side surface 60SC (refer to FIG. 2), in the Y-direction, than the drain pad 36 is. The source pad 35 is disposed at an end of the GaN unit 20A located toward the GaN unit 20B (refer to FIG. 2). In plan view, the source pad 35 is strip-shaped and extends in the X-direction.

As shown in FIG. 2, in plan view, the source pad 35 is arranged to overlap the interconnect layer 51. In the example shown in FIG. 2, the source pad 35 is longer than the interconnect layer 51 in length in the X-direction. The source pad 35 is electrically connected to the interconnect layer 51.

As shown in FIG. 3, multiple (in the present embodiment, two) gate pads 37 are arranged. The two gate pads 37 are separately arranged at opposite sides of the source pad 35 in the X-direction. Each gate pad 37 is arranged adjacent to the source pad 35 in the X-direction. In plan view, the gate pad 37 is rectangular so that the long sides extend in the Y-direction and the short sides extend in the X-direction. As shown in FIG. 2, in plan view, the two gate pads 37 are each arranged to overlap the first gate wiring layer 54.

As shown in FIG. 3, in plan view, the GaN unit 20A includes a cell region 38 between the source pad 35 and the drain pad 36 in the Y-direction. Multiple GaN transistors 22 (refer to FIG. 5) are formed in the cell region 38. Therefore, the GaN unit 20A includes the GaN transistor 22. In plan view, the cell region 38 is rectangular so that the long sides extend in the X-direction and the short sides extend in the Y-direction. As shown in FIG. 2, the first gate wiring layer 54 is arranged to partially overlap the cell region 38 (refer to FIG. 3) in plan view.

As shown in FIG. 2, the GaN units 20B, 20D, and 20F differ from the GaN units 20A, 20C, and 20E in the configuration of connection with the external wiring layer 50. The GaN units 20B, 20D, and 20F are the same in the configuration of connection with the external wiring layer 50. Thus, the connection configuration of the GaN unit 20B with the external wiring layer 50 will be described. The connection configuration of the GaN units 20D and 20F with the external wiring layer 50 will not be described in detail.

As shown in FIG. 2, the drain pad 36 of the GaN unit 20B is arranged to overlap the interconnect layer 51 in plan view. The drain pad 36 is electrically connected to the interconnect layer 51. That is, the drain pad 36 of the GaN unit 20B is electrically connected to the source pad 35 of the GaN unit 20A by the interconnect layer 51.

The source pad 35 of the GaN unit 20B is arranged to overlap the source wiring layer 53 in plan view. The source pad 35 is electrically connected to the source wiring layer 53. In the example shown in FIG. 2, the source pad 35 is greater than the source wiring layer 53 in length in the X-direction.

The multiple (in the present embodiment, two) gate pads 37 of the GaN unit 20B are arranged to overlap the second gate wiring layer 55 in plan view. The two gate pads 37 are arranged at opposite sides of the interconnect layer 51 in the X-direction in plan view.

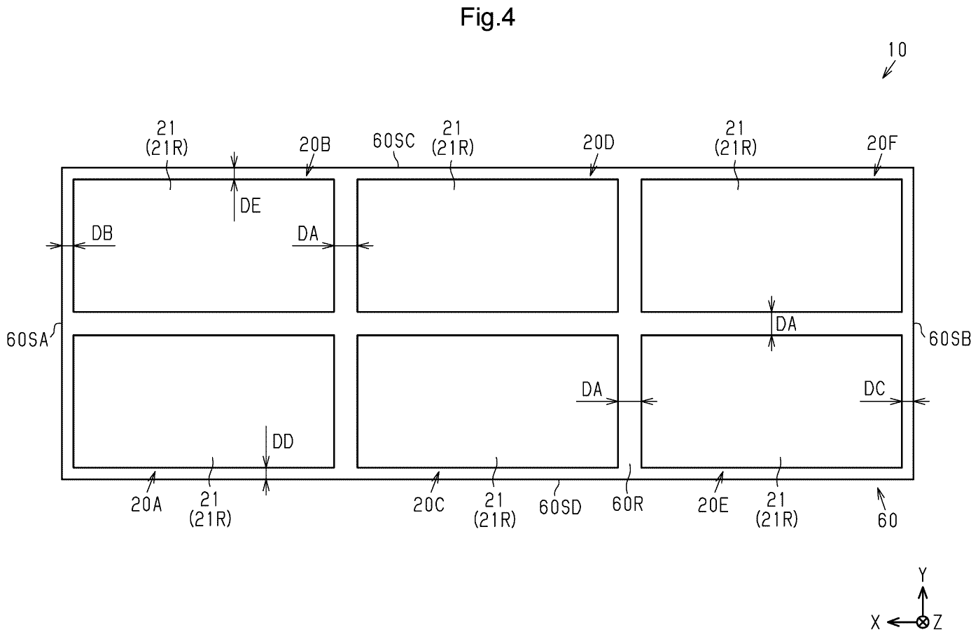

As shown in FIG. 4, in each of the GaN units 20A to 20F, the substrate back surface 21R of the substrate 21 is exposed from the encapsulation back surface 60R. In an example, the substrate back surfaces 21R are flush with the encapsulation back surface 60R. In an example, both the substrate back surfaces 21R and the encapsulation back surface 60R are polished, so that the substrate back surfaces 21R and the encapsulation back surface 60R are flush with each other. Therefore, polishing marks are formed on the substrate back surfaces 21R and the encapsulation back surface 60R.

A distance DA between adjacent ones of the substrates 21 is the same in the GaN units 20A to 20F. The distance DA is, for example, in a range of 10 μm to 50 μm, inclusive. A distance DB from the substrates 21 of the GaN units 20A and 20B to the first encapsulation side surface 60SA in the X-direction is less than the distance DA. The distance DB is, for example, less than ½ of the distance DA. A distance DC from the substrates 21 of the GaN units 20E and 20F to the second encapsulation side surface 60SB in the X-direction is less than the distance DA. The distance DC is, for example, less than ½ of the distance DA. The distance DC may be equal to the distance DB. A distance DD from the GaN units 20A, 20C, 20E to the fourth encapsulation side surface 60SD in the Y-direction is less than the distance DA. The distance DD is, for example, less than ½ of the distance DA. The distance DD may be equal to the distance DB. A distance DE from the substrates 21 of the GaN units 20B, 20D, and 20F to the third encapsulation side surface 60SC in the Y-direction is less than the distances DA. The distance DE is, for example, less than ½ of the distance DA. The distance DE may be equal to the distance DB. Also, the distance DE may be equal to the distance DD.

### Internal Structure of GaN Unit

FIG. 5 is a cross-sectional view showing a schematic cross-sectional structure of one of the GaN transistors 22 arranged in the cell region 38 of the GaN unit 20A. To facilitate understanding of the drawing, hatching lines are omitted from some components of the GaN transistor 22.

As shown in FIG. 5, the GaN transistor 22 is arranged at the side of the substrate front surface 21U (a substrate front surface side) of the substrate 21. A buffer layer 23 is arranged on the substrate front surface 21U of the substrate 21. The GaN transistor 22 is arranged on the buffer layer 23.

The buffer layer 23 may include one or more nitride semiconductor layers. The buffer layer 23 may be formed from, for example, any material that limits bending of the substrate 21 and formation of cracks in the GaN unit 20A caused by a mismatch in thermal expansion coefficient between the substrate 21 and an electron transit layer 24, which will be described later. For example, the buffer layer 23 may include at least one of an aluminum nitride (AlN) layer, an aluminum gallium nitride (AlGaN) layer, and a graded AlGaN layer having different aluminum (Al) compositions. For example, the buffer layer 23 may be composed of a single AlN layer, a single AlGaN layer, a layer having a superlattice structure of AlGaN/GaN, a layer having a superlattice structure of AlN/AlGaN, or a layer having a superlattice structure of AlN/GaN.

In an example, the buffer layer 23 includes a first buffer layer, which is an AlN layer formed on the substrate 21, and a second buffer layer, which is an AlGaN layer formed on the AlN layer (first buffer layer). The first buffer layer may be, for example, an AlN layer having a thickness in a range of 100 nm to 300 nm, inclusive. The second buffer layer may be formed, for example, by stacking graded AlGaN layers each having a thickness in a range of 100 nm to 300 nm, inclusive. To inhibit current leakage of the buffer layer 23, a portion of the buffer layer 23 may be doped with an impurity so that the buffer layer 23 becomes semi-insulating. In this case, the impurity is, for example, carbon (C) or iron (Fe). The concentration of the impurity may be, for example, greater than or equal to 4×10¹⁶ cm⁻³.

The GaN transistor 22 includes an electron transit layer 24, an electron supply layer 25, a gate layer 27, a gate electrode 28, a source electrode 29, a drain electrode 30, a first insulation film 31, and a second insulation film 32.

The electron transit layer 24 is formed on the buffer layer 23. The electron transit layer 24 is composed of a nitride semiconductor. The electron transit layer 24 may be, for example, a GaN layer. The electron transit layer 24 has a thickness in a range of, for example, 0.5 μm to 2 μm, inclusive. To inhibit current leakage in the electron transit layer 24, a portion of the electron transit layer 24 may be doped with an impurity so that the electron transit layer 24 excluding an outer layer region becomes semi-insulating. In this case, the impurity is, for example, C. The peak concentration of the impurity in the electron transit layer 24 may be, for example, greater than or equal to 1×10¹⁹ cm⁻³.

The electron supply layer 25 is formed on the electron transit layer 24. The electron supply layer 25 is composed of a nitride semiconductor having a larger band gap than the electron transit layer 24 and may be, for example, an AlGaN layer. In this case, the bandgap becomes larger as the Al composition increases. Thus, the electron supply layer 25, which is an AlGaN layer, has a larger band gap than the electron transit layer 24, which is a GaN layer. In an example, the electron supply layer 25 is composed of AlₓGa₁₋ₓN, where 0.1<x<0.4, and, more preferably, 0.1<x<0.3. The electron supply layer 25 may have a thickness in a range of 5 nm to 20 nm, inclusive. In an example, the electron supply layer 25 may have a thickness that is greater than or equal to 8 nm.

The electron transit layer 24 and the electron supply layer 25 are composed of nitride semiconductors having different lattice constants. Thus, the nitride semiconductor forming the electron transit layer 24 (e.g., GaN) and the nitride semiconductor forming the electron supply layer 25 (e.g., AlGaN) form a lattice-mismatching heterojunction. The energy level of the conduction band of the electron transit layer 24 in the vicinity of the heterojunction interface is lower than the Fermi level due to spontaneous polarization of the electron transit layer 24 and the electron supply layer 25 and piezoelectric polarization caused by stress applied to the electron supply layer 25 in the vicinity of the heterojunction interface. As a result, at a location close to the heterojunction interface between the electron transit layer 24 and the electron supply layer 25 (e.g., within range approximately a few nanometers from the interface), a two-dimensional electron gas 26 (2DEG) spreads in the electron transit layer 24.

The gate layer 27 is formed on the electron supply layer 25. More specifically, the gate layer 27 is formed on a portion of the electron supply layer 25. The gate layer 27 is composed of a nitride semiconductor containing an acceptor impurity. The gate layer 27 may be composed of any material having a smaller band gap than the electron supply layer 25 (e.g., AlGaN layer). In an example, the gate layer 27 may be a GaN (p-type GaN) layer containing an acceptor impurity. The acceptor impurity may contain at least one of zinc (Zn), magnesium (Mg), and carbon (C). The peak concentration of the acceptor impurity in the gate layer 27 may be in a range of 7×10¹⁸ cm⁻³ to 1×10²⁰ cm⁻³, inclusive. In an example, the gate layer 27 may be a GaN layer containing at least one of Mg and Zn as an impurity.

The gate electrode 28 is arranged above the electron supply layer 25. The gate electrode 28 may be formed of one or more metal layers. In an example, the gate electrode 28 may be composed of a titanium nitride (TiN) layer. In another example, the gate electrode 28 may include a first metal layer formed from titanium (Ti) and a second metal layer formed on the first metal layer and formed from TiN. The gate electrode 28 may form a Schottky junction with the gate layer 27.

The first insulation film 31 may be formed on a portion of the gate layer 27. The first insulation film 31 may be sandwiched between the gate layer 27 and the gate electrode 28. The first insulation film 31 may be formed from, for example, at least one of silicon nitride (Si₃N₄), silicon dioxide (SiO₂), silicon oxynitride (SiON), aluminum oxide (Al₂O₃), AlN, and aluminum oxynitride (AlON). In an example, the first insulation film 31 may be formed from Si₃N₄. The first insulation film 31 has an opening 31A exposing the gate layer 27.

The gate electrode 28 is in contact with the gate layer 27 and the first insulation film 31. The gate electrode 28 includes a gate contact portion that is in contact with the gate layer 27 via the opening 31A in the first insulation film 31, and a gate field plate portion formed on the first insulation film 31. The gate field plate portion is continuous with the gate contact portion and is formed integrally with the gate contact portion.

The second insulation film 32 covers the electron supply layer 25, the gate layer 27, the first insulation film 31, and the gate electrode 28. The second insulation film 32 has a first opening 32A and a second opening 32B that expose the surface of the electron supply layer 25. The first opening 32A and the second opening 32B are separate from each other. The gate layer 27 is located between the first opening 32A and the second opening 32B and is spaced apart from the first opening 32A and the second opening 32B. More specifically, the gate layer 27 is located closer to the first opening 32A than to the second opening 32B.

The second insulation film 32 is, for example, a passivation film, and may be composed of at least one of Si₃N₄, SiO₂, SiON, Al₂O₃, and AlN. In an example, the second insulation film 32 may be formed from Si₃N₄. That is, the first insulation film 31 and the second insulation film 32 may be formed from the same material. The second insulation film 32 may have a thickness, for example, in a range of 80 nm to 200 nm, inclusive.

The source electrode 29 is in contact with the electron supply layer 25 through the first opening 32A of the second insulation film 32. The source electrode 29 is in ohmic contact with the 2DEG 26 present immediately below the electron supply layer 25 through the first opening 32A. In an example, the source electrode 29 may include a source contact portion 29A filling the first opening 32A and a source field plate portion 29B covering the second insulation film 32. The source field plate portion 29B is continuous with the source contact portion 29A and is formed integrally with the source contact portion 29A. The source field plate portion 29B includes an end 29C located between the second opening 32B and the gate layer 27 in plan view. The source field plate portion 29B mitigates electric field concentration at the vicinity of the end of the gate electrode 28 and the vicinity of the end of the gate layer 27 when a gate voltage is applied to the gate electrode 28.

The drain electrode 30 is in contact with the electron supply layer 25 through the second opening 32B in the second insulation film 32. The drain electrode 30 is in ohmic contact with the 2DEG 26 present immediately below the electron supply layer 25 through the second opening 32B. Each of the drain electrode 30 and the source electrode 29 may be composed of one or more metal layers (e.g., any combination of a Ti layer, a TiN layer, an Al layer, an AlSiCu layer, an AlCu layer, and the like).

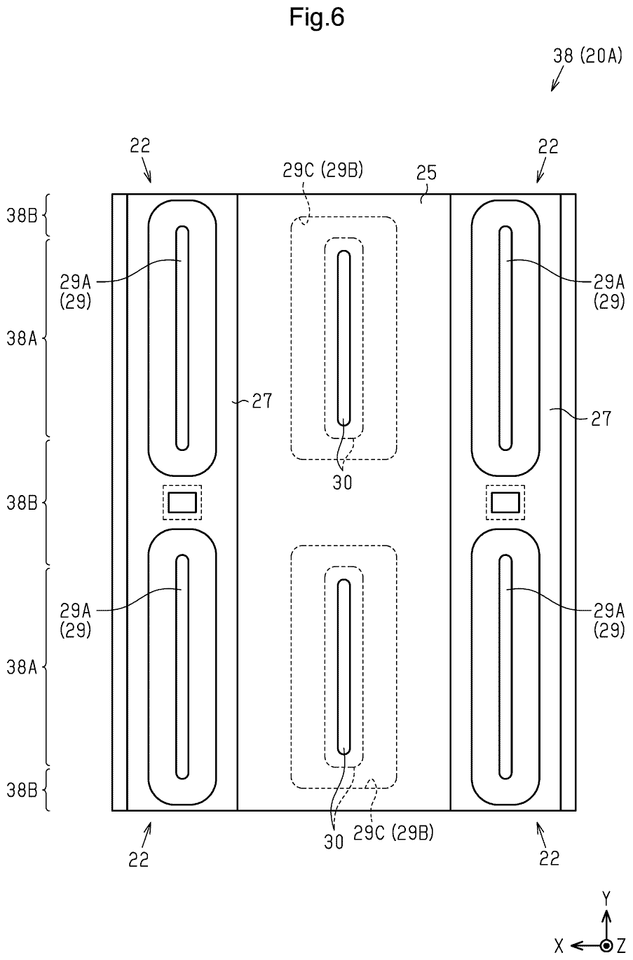

An example of the planar structure of the GaN transistor 22 will now be described. FIG. 6 is a schematic enlarged partial plan view of the GaN transistor 22 shown in FIG. 5. For the sake of simplicity to facilitate understanding, FIG. 6 does not show the gate electrode 28, the second insulation film 32, and the source field plate portion 29B of the source electrode 29. The end 29C of the source field plate portion 29B is indicated by broken lines. The portion of the drain electrode 30 in contact with the electron supply layer 25 is indicated by solid lines, whereas the portion of the drain electrode 30 arranged on the second insulation film 32 is indicated by broken lines.

As shown in FIG. 6, the cell region 38 includes an active region 38A that contributes to the transistor operation of the GaN transistor 22 and a non-active region 38B that does not contribute to the transistor operation. In the example shown in FIG. 6, active regions 38A and non-active regions 38B are alternately arranged. The drain electrodes 30 are formed in the active regions 38A. In an example, in the arrangement direction of the active regions 38A and the non-active regions 38B, the active regions 38A may extend in substantially the same range as the drain electrodes 30. In the arrangement direction, the non-active regions 38B may extend in a range where the drain electrodes 30 are absent. Thus, the non-active regions 38B are arranged adjacent to the active regions 38A in the arrangement direction.

In the active region 38A, the source electrode 29, the gate layer 27 on which the gate electrode 28 (refer to FIG. 5) is located, and the drain electrode 30 are arranged adjacent to each other on the electron supply layer 25 in a direction orthogonal to the arrangement direction in plan view. This combination of the source electrode 29, the gate layer 27 (gate electrode 28), and the drain electrode 30 form a single GaN transistor 22. In the example shown in FIG. 6, four GaN transistors 22 are arranged in each active region 38A. In practical use, more GaN transistors 22 may be arranged in each active region 38A.

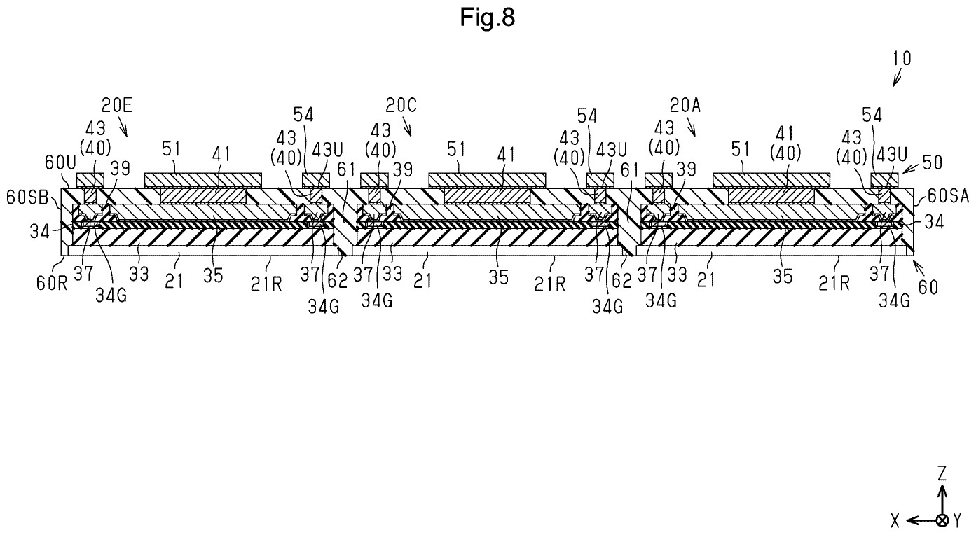

FIG. 7 is a cross-sectional view showing a schematic cross-sectional structure of the semiconductor device 10 taken along line F7-F7 in FIG. 2. FIG. 7 shows a schematic cross-sectional structure of the GaN units 20A and 20B. FIG. 8 is a cross-sectional view showing a schematic cross-sectional structure of the semiconductor device 10 taken along line F8-F8 in FIG. 2. FIG. 8 shows a schematic cross-sectional structure of the GaN units 20A, 20C, and 20E. To facilitate understanding of the drawings, FIGS. 7 and 8 do not show the structure of the GaN transistor 22 shown in FIG. 5.

As shown in FIGS. 7 and 8, the GaN transistor 22 of the GaN unit 20A has the same structure as the GaN transistor 22 of the GaN unit 20B. The GaN transistor 22 of the GaN unit 20A has the same structure as the GaN transistors 22 of the GaN units 20C and 20E. Although not shown, the GaN transistor 22 of the GaN unit 20A has the same structure as the GaN transistors 22 of the GaN units 20D and 20F. Thus, the GaN units 20A to 20F include the GaN transistors 22 having the same configuration.

The GaN transistor 22 includes a third insulation film 33 and a wiring layer 34. The GaN transistor 22 includes the source pad 35, the drain pad 36, and the gate pad 37, which are described above.

The third insulation film 33 is configured to cover the source electrode 29 and the drain electrode 30 (not shown in FIGS. 7 and 8, refer to FIG. 5). The third insulation film 33 is an interlayer insulation film and is formed from, for example, SiO₂.

The wiring layer 34 electrically connects the gate electrode 28 (not shown in FIGS. 7 and 8, refer to FIG. 5), the source electrode 29, and the drain electrode 30 to the gate pad 37, the source pad 35, and the drain pad 36, respectively.

The wiring layer 34 includes a source wiring portion 34S electrically connecting the source electrode 29 and the source pad 35, a drain wiring portion 34D electrically connecting the drain electrode 30 and the drain pad 36, and a gate wiring portion 34G electrically connecting the gate electrode 28 and the gate pad 37 (refer to FIG. 8). Each of the source wiring portion 34S, the drain wiring portion 34D, and the gate wiring portion 34G includes a portion arranged on the third insulation film 33.

The source wiring portion 34S includes source contacts (not shown) arranged to overlap the source electrode 29 in plan view. The source contacts extend through the third insulation film 33 in the Z-direction and are in contact with the source electrode 29.

The drain wiring portion 34D includes drain contacts (not shown) arranged to overlap the drain electrode 30 in plan view. The drain contacts extend through the third insulation film 33 in the Z-direction and are in contact with the drain electrode 30.

The gate wiring portion 34G includes gate contacts (not shown) arranged to overlap the gate electrode 28 in plan view. The gate contacts extend through the third insulation film 33 in the Z-direction and are in contact with the gate electrode 28.

Each of the source wiring portion 34S, the drain wiring portion 34D, and the gate wiring portion 34G is formed of, for example, multiple metal layers. For example, each of the source wiring portion 34S, the drain wiring portion 34D, and the gate wiring portion 34G is formed of an electrolytic plating. Each of the source wiring portion 34S, the drain wiring portion 34D, and the gate wiring portion 34G is formed of, for example, a Ti layer as a seed layer and a Cu layer as a plating layer.

The wiring layer 34 includes a fourth insulation film 34A that insulates the source wiring portion 34S, the drain wiring portion 34D, and the gate wiring portion 34G from each other. The fourth insulation film 34A is arranged on the third insulation film 33. In an example, the fourth insulation film 34A is equal in thickness to the source wiring portion 34S, the drain wiring portion 34D, and the gate wiring portion 34G. The fourth insulation film 34A is less in thickness than the third insulation film 33. The fourth insulation film 34A is an interlayer insulation film and is formed from, for example, SiO₂.

The source pad 35, the drain pad 36, and the gate pad 37 (refer to FIG. 8) are arranged on the wiring layer 34.

The source pad 35 is arranged to overlap the source wiring portion 34S in plan view. In other words, the source wiring portion 34S is arranged to overlap the source pad 35 in plan view. The source pad 35 includes a contact portion in contact with the source wiring portion 34S.

The drain pad 36 is arranged to overlap the drain wiring portion 34D in plan view. In other words, the drain wiring portion 34D is arranged to overlap the drain pad 36 in plan view. The drain pad 36 includes a contact portion in contact with the drain wiring portion 34D.

The gate pad 37 shown in FIG. 8 is arranged to overlap the gate wiring portion 34G in plan view. In other words, the gate wiring portion 34G is arranged to overlap the gate pad 37 in plan view. The gate pad 37 includes a contact portion that is in contact with the gate wiring portion 34G.

Each of the source pad 35, the drain pad 36, and the gate pad 37 is formed of, for example, multiple metal layers. In an example, each of the source pad 35, the drain pad 36, and the gate pad 37 is formed of an electrolytic plating. Each of the source pad 35, the drain pad 36, and the gate pad 37 is formed of, for example, a Ti layer as a seed layer and a Cu layer as a plating layer.

The GaN transistor 22 includes a fifth insulation film 39 that insulates the source pad 35, the drain pad 36, and the gate pad 37 from each other. In an example, the fifth insulation film 39 is equal in thickness to the source pad 35, the drain pad 36, and the gate pad 37. The fifth insulation film 39 is less than or equal to the third insulation film 33 in thickness. The fifth insulation film 39 is an interlayer insulation film and is formed from, for example, SiO₂.

As shown in FIGS. 2, 7, and 8, the GaN unit 20A includes a post 40 arranged on the source pad 35, the drain pad 36, and the gate pad 37 of the GaN transistor 22 and exposed from the first encapsulation resin 60. The post 40 is exposed from the encapsulation front surface 60U of the first encapsulation resin 60.

The post 40 includes a source post 41, a drain post 42, and a gate post 43. The source post 41, the drain post 42, and the gate post 43 are spaced apart from each other in a direction orthogonal to the thickness-wise direction (Z-direction) of the first encapsulation resin 60. The first encapsulation resin 60 is arranged between the source post 41, the drain post 42, and the gate post 43 in the direction orthogonal to the thickness-wise direction of the first encapsulation resin 60. Thus, the source post 41, the drain post 42, and the gate post 43 are insulated by the first encapsulation resin 60.

The source post 41 includes an upper surface 41U exposed from the encapsulation front surface 60U. The drain post 42 includes an upper surface 42U exposed from the encapsulation front surface 60U. The gate post 43 includes an upper surface 43U exposed from the encapsulation front surface 60U. As shown in FIGS. 7 and 8, the upper surface 41U of the source post 41, the upper surface 42U of the drain post 42, the upper surface 43U of the gate post 43, and the encapsulation front surface 60U are flush with each other. In an example, all of the upper surface 41U of the source post 41, the upper surface 42U of the drain post 42, the upper surface 43U of the gate post 43, and the encapsulation front surface 60U are polished, so that the upper surface 41U of the source post 41, the upper surface 42U of the drain post 42, the upper surface 43U of the gate post 43, and the encapsulation front surface 60U are flush with each other. Hence, polishing marks are formed on the upper surface 41U of the source post 41, the upper surface 42U of the drain post 42, the upper surface 43U of the gate post 43, and the encapsulation front surface 60U.

The source post 41 is arranged on the source pad 35. The source post 41 is in contact with the source pad 35. The source post 41 is electrically connected to the source electrode 29 (refer to FIG. 5) by the source pad 35 and the source wiring portion 34S.

As shown in FIG. 2, the source post 41 is strip-shaped and extends in the X-direction in plan view. In the example shown in FIG. 2, the source post 41 is less than the source pad 35 in width-wise dimension (dimension in the Y-direction). The source post 41 is less than the source pad 35 in length-wise dimension (dimension in the X-direction).

The interconnect layer 51 is arranged, as the external wiring layer 50, on the source post 41. The interconnect layer 51 is greater than the source post 41 in width-wise dimension (dimension in the Y-direction). The interconnect layer 51 is greater than the source post 41 in length-wise dimension (dimension in the X-direction). Thus, in plan view, the interconnect layer 51 extends out from the source post 41 in the X-direction and the Y-direction. The part of the interconnect layer 51 extending out from the source post 41 in plan view is arranged on the encapsulation front surface 60U.

As shown in FIG. 7, the drain post 42 is arranged on the drain pad 36. The drain post 42 is in contact with the drain pad 36. The drain post 42 is electrically connected to the drain electrode 30 (refer to FIG. 5) by the drain pad 36 and the drain wiring portion 34D.

As shown in FIG. 2, the drain post 42 is strip-shaped and extends in the X-direction in plan view. In the example shown in FIG. 2, the drain post 42 is less than the drain pad 36 in width-wise dimension (dimension in the Y-direction). The drain post 42 is less than the drain pad 36 in length-wise dimension (dimension in the X-direction).

The drain wiring layer 52 is arranged, as the external wiring layer 50, on the drain post 42. The drain wiring layer 52 is greater than the drain post 42 in width-wise dimension (dimension in the Y-direction). The drain wiring layer 52 is greater than the drain post 42 in length-wise dimension (dimension in the X-direction). Thus, in plan view, the drain wiring layer 52 extends out from the drain post 42 in the X-direction and the Y-direction. The part of the drain wiring layer 52 extending out from the drain post 42 in plan view is arranged on the encapsulation front surface 60U.

As shown in FIG. 8, the gate post 43 is arranged on the gate pad 37. The number of gate posts 43 corresponds to the number of gate pads 37. In the example shown in FIG. 8, two gate posts 43 are arranged corresponding to the two gate pads 37. Each of the gate posts 43 is electrically connected to the gate electrode 28 (refer to FIG. 5) by the gate pad 37 and the gate wiring portion 34G.

As shown in FIG. 2, the gate post 43 is rectangular in plan view so that the short sides extend in the X-direction and the long sides extend in the Y-direction. In the example shown in FIG. 2, the gate post 43 is less than the gate pad 37 in width-wise dimension (dimension in the X-direction). The gate post 43 is less than the gate pad 37 in length-wise dimension (dimension in the Y-direction).

The first gate wiring layer 54 is arranged, as the external wiring layer 50, on each gate post 43. The first gate wiring layer 54 has a width-wise dimension (dimension in a direction orthogonal to a direction in which the first gate wiring layer 54 extends in plan view) that is greater than the width-wise dimension of the gate post 43. The first gate wiring layer 54 is arranged to electrically connect the two gate posts 43.

The GaN units 20C and 20E each include the post 40 in the same manner as the GaN unit 20A. The positional relationship and the dimensional relationship between the post 40 of each of the GaN units 20C and 20E and the external wiring layer 50 are the same as those of the GaN unit 20A.

The GaN unit 20B includes the post 40 in the same manner as the GaN unit 20A. The positional relationship and the dimensional relationship between the source post 41 and the source pad 35 of the GaN unit 20B are the same as the positional relationship and the dimensional relationship between the source post 41 and the source pad 35 of the GaN unit 20A. The positional relationship and the dimensional relationship between the drain post 42 and the drain pad 36 of the GaN unit 20B are the same as the positional relationship and the dimensional relationship between the drain post 42 and the drain pad 36 of the GaN unit 20A. The positional relationship and the dimensional relationship between the gate post 43 and the gate pad 37 of the GaN unit 20B are the same as the positional relationship and the dimensional relationship between the gate post 43 and the gate pad 37 of the GaN unit 20A.

The positional relationship and the dimensional relationship between the GaN unit 20B and the external wiring layer 50 differ from the positional relationship and the dimensional relationship between the GaN unit 20A and the external wiring layer 50.

More specifically, the interconnect layer 51 is arranged on the drain post 42 of the GaN unit 20B. The interconnect layer 51 is greater than the drain post 42 in width-wise dimension (dimension in the Y-direction). The interconnect layer 51 is greater than the drain post 42 in length-wise dimension (dimension in the X-direction). Thus, in plan view, the interconnect layer 51 extends out from the drain post 42 in the X-direction and the Y-direction. The part of the interconnect layer 51 extending out from the drain post 42 in plan view is arranged on the encapsulation front surface 60U.

The source wiring layer 53 is arranged on the source post 41 of the GaN unit 20B. The source wiring layer 53 is greater than the source post 41 in width-wise dimension (dimension in the Y-direction). The source wiring layer 53 is greater than the source post 41 in length-wise dimension (dimension in the X-direction). Thus, in plan view, the source wiring layer 53 extends out from the source post 41 in the X-direction and the Y-direction. The part of the source wiring layer 53 extending out from the source post 41 in plan view is arranged on the encapsulation front surface 60U.

The second gate wiring layer 55 is arranged on each gate post 43 of the GaN unit 20B. The second gate wiring layer 55 has a width-wise dimension (dimension in a direction orthogonal to a direction in which the second gate wiring layer 55 extends in plan view) that is greater than the width-wise dimension of the gate post 43. The second gate wiring layer 55 is arranged to electrically connect the two gate posts 43.

The GaN units 20D and 20F each include the post 40 in the same manner as the GaN unit 20B. The positional relationship and the dimensional relationship between the post 40 of each of the GaN units 20D and 20F and the external wiring layer 50 are the same as those of the GaN unit 20B.

The configuration of connection of the GaN unit 20A and the GaN unit 20B with the external wiring layer 50 will now be described.

As shown in FIGS. 2 and 7, the drain post 42 of the GaN unit 20A is electrically connected to the drain wiring layer 52. The source post 41 of the GaN unit 20A and the drain post 42 of the GaN unit 20B are electrically connected to the interconnect layer 51. The source post 41 of the GaN unit 20B is electrically connected to the source wiring layer 53. The two gate posts 43 of the GaN unit 20A are electrically connected to the first gate wiring layer 54. The two gate posts 43 of the GaN unit 20B are electrically connected to the second gate wiring layer 55.

Thus, the source electrode 29 of the GaN unit 20A and the drain electrode 30 of the GaN unit 20B are electrically connected by the interconnect layer 51. That is, the GaN unit 20B is electrically connected to the GaN unit 20A.

The GaN unit 20C and the GaN unit 20D are electrically connected to each other. The GaN unit 20E and the GaN unit 20F are electrically connected to each other. The configuration of electrical connection of the GaN unit 20C with the GaN unit 20D and the configuration of electrical connection of the GaN unit 20E with the GaN unit 20F are the same as the configuration of electrical connection of the GaN unit 20A with the GaN unit 20B.

The semiconductor device 10 includes the interconnect layer 51 that electrically connects the source post 41 formed on the source pad 35 of one of the two GaN units located adjacent to each other in the first direction (Y-direction) and the drain post 42 formed on the drain pad 36 of the other of the two GaN units located adjacent to each other in the first direction (Y-direction).

As shown in FIGS. 2, 7, and 8, the first encapsulation resin 60 encapsulates the GaN units 20A to 20F. As shown in FIG. 7, the first encapsulation resin 60 is arranged between the GaN units 20A and the GaN units 20B.

As shown in FIG. 7, the first encapsulation resin 60 includes a wiring encapsulation layer 61 and a substrate encapsulation layer 62. The wiring encapsulation layer 61 and the substrate encapsulation layer 62 are defined for the sake of convenience. There is no interface between the wiring encapsulation layer 61 and the substrate encapsulation layer 62.

As shown in FIGS. 7 and 8, the wiring encapsulation layer 61 is arranged between the wiring layer 34 of the GaN unit 20A and the wiring layer 34 of the GaN unit 20B. The wiring encapsulation layer 61 is arranged between the wiring layer 34 of the GaN unit 20A and the wiring layer 34 of the GaN unit 20C, and between the wiring layer 34 of the GaN unit 20C and the wiring layer 34 of the GaN unit 20E. Although not shown, the wiring encapsulation layer 61 is also arranged between the wiring layer 34 of the GaN unit 20C and the wiring layer 34 of the GaN unit 20D, and between the wiring layer 34 of the GaN unit 20E and the wiring layer 34 of the GaN unit 20F. The wiring encapsulation layer 61 is arranged between the wiring layer 34 of the GaN unit 20B and the wiring layer 34 of the GaN unit 20D, and between the wiring layer 34 of the GaN unit 20D and the wiring layer 34 of the GaN unit 20F. Thus, among the wiring layers 34 of the GaN units 20A to 20F, the wiring encapsulation layer 61 is arranged between the wiring layers 34 located adjacent to each other in the X-direction or the Y-direction and insulates the wiring layers 34 of the GaN units 20A to 20F from each other. In other words, the first encapsulation resin 60 covers the wiring layers 34 of the GaN units 20A to 20F and is arranged between the wiring layers 34 located adjacent to each other in the X-direction or the Y-direction.

The substrate encapsulation layer 62 is arranged between the substrate 21 of the GaN unit 20A and the substrate 21 of the GaN unit 20B. The substrate encapsulation layer 62 is arranged between the substrate 21 of the GaN unit 20A and the substrate 21 of the GaN unit 20C, and between the substrate 21 of the GaN unit 20C and the substrate 21 of the GaN unit 20E. Although not shown, the substrate encapsulation layer 62 is arranged between the substrate 21 of the GaN unit 20C and the substrate 21 of the GaN unit 20D, and between the substrate 21 of the GaN unit 20E and the substrate 21 of the GaN unit 20F. The substrate encapsulation layer 62 is arranged between the substrate 21 of the GaN unit 20B and the substrate 21 of the GaN unit 20D, and between the substrate 21 of the GaN unit 20D and the substrate 21 of the GaN unit 20F. Thus, among the substrates 21 of the GaN units 20A to 20F, the substrate encapsulation layer 62 is arranged between the substrates 21 located adjacent to each other in the X-direction or the Y-direction and insulates the substrates 21 of the GaN units 20A to 20F from each other. In other words, the first encapsulation resin 60 covers the substrates 21 of the GaN units 20A to 20F excluding the substrate back surfaces 21R and is arranged between the substrates 21 located adjacent to each other in the X-direction or the Y-direction.

As shown in FIG. 7, in the GaN units 20A and 20B, located adjacent to each other in the Y-direction (first direction), a dimension HA of the wiring encapsulation layer 61 in the Y-direction (first direction) is greater than a dimension HB of the substrate encapsulation layer 62 in the Y-direction (first direction). The dimension BB is equal to the distance DA (refer to FIG. 4) between adjacent ones of the substrates 21.

A dimension HC, in the Y-direction, of the wiring encapsulation layer 61 between the fourth encapsulation side surface 60SD and the wiring layer 34 of the GaN unit 20A is greater than a dimension HD, in the Y-direction, of the substrate encapsulation layer 62 between the fourth encapsulation side surface 60SD and the substrate 21 of the GaN unit 20A. A dimension HE, in the Y-direction, of the wiring encapsulation layer 61 between the third encapsulation side surface 60SC and the wiring layer 34 of the GaN unit 20B is greater than a dimension HF, in the Y-direction, of the substrate encapsulation layer 62 between the third encapsulation side surface 60SC and the substrate 21 of the GaN unit 20B. The dimension HC and the dimension HE are each smaller than the dimension HA. The dimension HC is equal to the dimension HE. The dimension HD and the dimension HF are each smaller than the dimension HB. The dimension HD is equal to the dimension HF. The dimension HD is equal to the distance DD (refer to FIG. 4) between the substrate 21 of the GaN unit 20A and the fourth encapsulation side surface 60SD in the Y-direction. The dimension HF is equal to the distance DE (refer to FIG. 4) between the substrate 21 of the GaN unit 20B and the third encapsulation side surface 60SC in the Y-direction.

Although not shown, the GaN units 20C and 20D also have the relationship of the dimensions HA to HF of the GaN units 20A and 20B. In addition, the GaN units 20E and 20F have the relationship of the dimensions HA to HF of the GaN units 20A and 20B.

Although not shown, in the GaN units 20A, 20C, and 20E located adjacent to each other in the X-direction (second direction), a first dimension of the wiring encapsulation layer 61 in the X-direction (second direction) is greater than a second dimension of the substrate encapsulation layer 62 in the X-direction (second direction). The second dimension is equal to the distance DA (refer to FIG. 4) between adjacent ones of the substrates 21.

A third dimension, in the X-direction, of the wiring encapsulation layer 61 between the first encapsulation side surface 60SA and the wiring layer 34 of the GaN unit 20A is greater than a fourth dimension, in the X-direction, of the substrate encapsulation layer 62 between the first encapsulation side surface 60SA and the substrate 21 of the GaN unit 20A. A fifth dimension, in the X-direction, of the wiring encapsulation layer 61 between the second encapsulation side surface 60SB and the wiring layer 34 of the GaN unit 20E is greater than a sixth dimension, in the X-direction, of the substrate encapsulation layer 62 between the second encapsulation side surface 60SB and the substrate 21 of the GaN unit 20E. The third dimension and the fifth dimension are each less than the first dimension. The third dimension is equal to the fifth dimension. The fourth dimension and the sixth dimension are each less than the second dimension. The fourth dimension is equal to the sixth dimension. The GaN units 20B, 20D, and 20F also have the relationship of the first to sixth dimensions of the GaN units 20A, 20C, and 20E. The fourth dimension is equal to the distance DB between the substrate 21 of the GaN unit 20A and the first encapsulation side surface 60SA in the X-direction. The sixth dimension is equal to the distance DC between the substrate 21 of the GaN unit 20E and the second encapsulation side surface 60SB in the X-direction.

As shown in FIG. 7, the first encapsulation resin 60 covers the wiring layers 34 of the GaN units 20A and 20B. As shown in FIG. 8, the first encapsulation resin 60 covers the wiring layers 34 of the GaN units 20A, 20C, and 20E. Although not shown, the first encapsulation resin 60 covers the wiring layers 34 of the GaN units 20D and 20F. Thus, the first encapsulation resin 60 covers the wiring layers 34 of the GaN units 20A to 20F. The first encapsulation resin 60 covers each of the drain pad 36, the source pad 35, and the gate pad 37 exposed from the wiring layers 34 of the GaN units 20A to 20F. More specifically, the portion of the drain pad 36 extending out from the drain post 42 in plan view, the portion of the source pad 35 extending out from the source post 41 in plan view, and the portion of the gate pad 37 extending out from the gate post 43 in plan view are covered by the first encapsulation resin 60.

### Circuit Configuration of Semiconductor Device

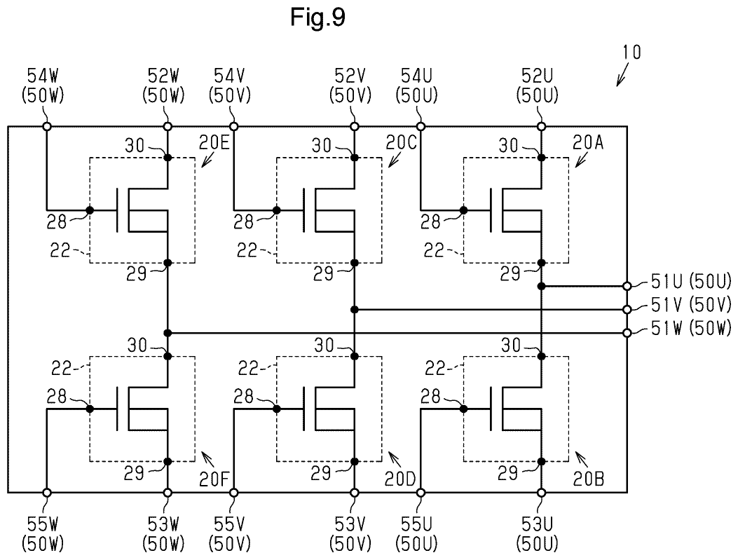

An example of a circuit configuration of the semiconductor device 10 will now be described. FIG. 9 shows a schematic circuit configuration of the semiconductor device 10. In the description of the circuit configuration of the semiconductor device 10, the external wiring layer 50 is referred to as an “external wiring layer 50U”, an “external wiring layer 50V”, and an “external wiring layer 50W.” For the sake of convenience, “U”, “V”, and “W” are also added to the interconnect layer 51, the drain wiring layer 52, the source wiring layer 53, the first gate wiring layer 54, and the second gate wiring layer 55 of the external wiring layer 50.

As shown in FIG. 9, the semiconductor device 10 includes the GaN transistors 22 of the GaN units 20A and 20B connected in series, the GaN transistors 22 of the GaN units 20C and 20D connected in series, and the GaN transistors 22 of the GaN units 20E and 20F connected in series. The semiconductor device 10 also includes an external wiring layer 50U corresponding to the GaN units 20A and 20B, an external wiring layer 50V corresponding to the GaN units 20C and 20D, and an external wiring layer 50W corresponding to the GaN units 20E and 20F.

The source electrode 29 of the GaN transistor 22 of the GaN unit 20A is electrically connected to the drain electrode 30 of the GaN transistor 22 of the GaN unit 20B. The interconnect layer 51U is electrically connected to a node between the source electrode 29 of the GaN transistor 22 of the GaN unit 20A and the drain electrode 30 of the GaN transistor 22 of the GaN unit 20B. The drain electrode 30 of the GaN transistor 22 of the GaN unit 20A is electrically connected to the drain wiring layer 52U. The source electrode 29 of the GaN transistor 22 of the GaN unit 20B is electrically connected to the source wiring layer 53U. The gate electrode 28 of the GaN transistor 22 of the GaN unit 20A is electrically connected to the first gate wiring layer 54U. The gate electrode 28 of the GaN transistor 22 of the GaN unit 20B is electrically connected to the second gate wiring layer 55U.

The source electrode 29 of the GaN transistor 22 of the GaN unit 20C is electrically connected to the drain electrode 30 of the GaN transistor 22 of the GaN unit 20D. The interconnect layer 51U is electrically connected to a node between the source electrode 29 of the GaN transistor 22 of the GaN unit 20C and the drain electrode 30 of the GaN transistor 22 of the GaN unit 20D. The drain electrode 30 of the GaN transistor 22 of the GaN unit 20C is electrically connected to the drain wiring layer 52V. The source electrode 29 of the GaN transistor 22 of the GaN unit 20D is electrically connected to the source wiring layer 53V The gate electrode 28 of the GaN transistor 22 of the GaN unit 20C is electrically connected to the first gate wiring layer 54V. The gate electrode 28 of the GaN transistor 22 of the GaN unit 20D is electrically connected to the first gate wiring layer 55V.

The source electrode 29 of the GaN transistor 22 of the GaN unit 20E is electrically connected to the drain electrode 30 of the GaN transistor 22 of the GaN unit 20F. The interconnect layer 51W is electrically connected to a node between the source electrode 29 of the GaN transistor 22 of the GaN unit 20E and the drain electrode 30 of the GaN transistor 22 of the GaN unit 20F. The drain electrode 30 of the GaN transistor 22 of the GaN unit 20E is electrically connected to the drain wiring layer 52W. The source electrode 29 of the GaN transistor 22 of the GaN unit 20F is electrically connected to the source wiring layer 53W. The gate electrode 28 of the GaN transistor 22 of the GaN unit 20E is electrically connected to the first gate wiring layer 54W. The gate electrode 28 of the GaN transistor 22 of the GaN unit 20F is electrically connected to the second gate wiring layer 55W.

The GaN transistors 22 of the GaN units 20A and 20B, the GaN transistors 22 of the GaN units 20C and 20D, and the GaN transistors of the GaN units 20E and 20F are insulated from each other.

### Overall Configuration of Semiconductor Module

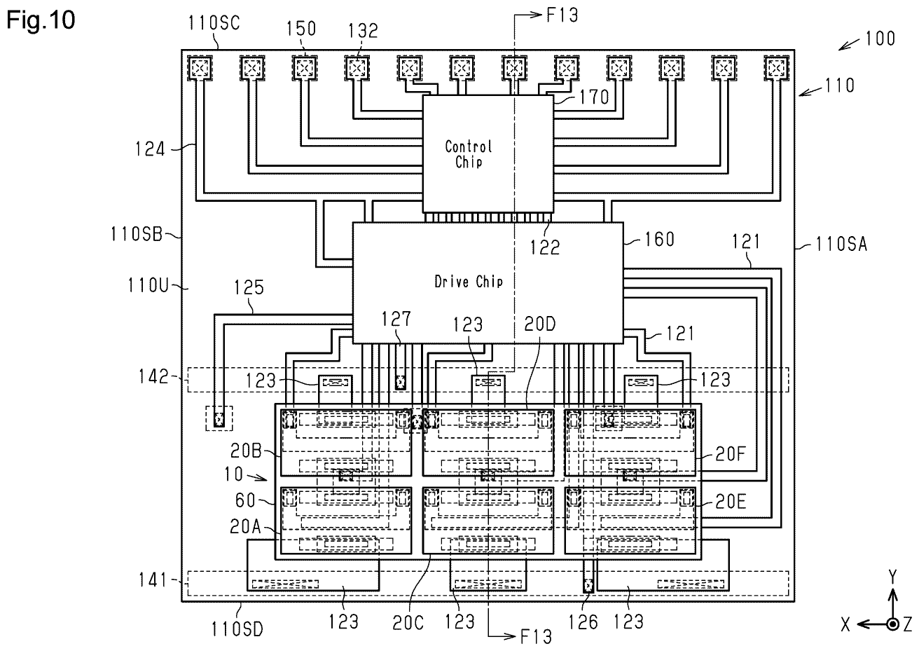

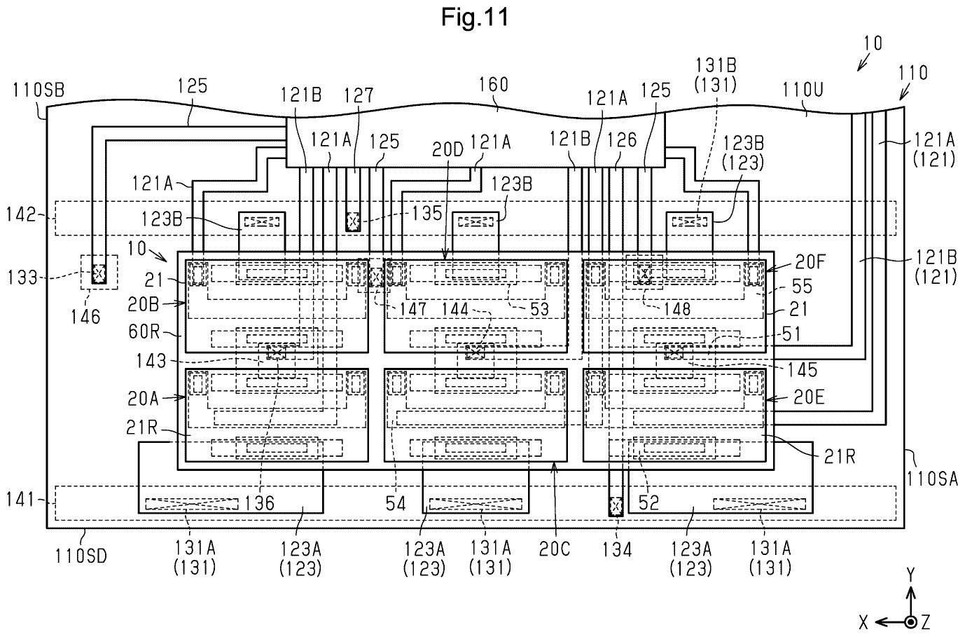

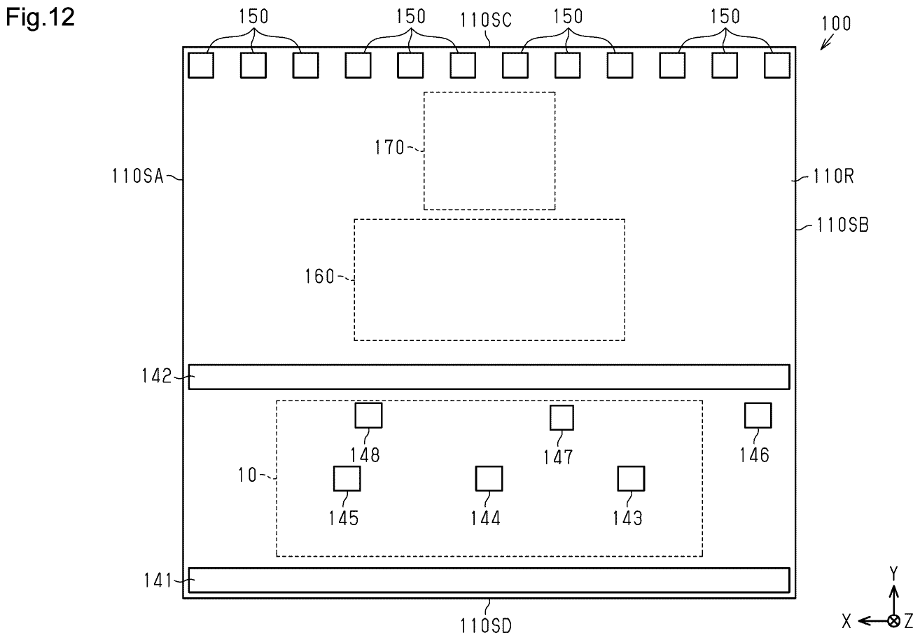

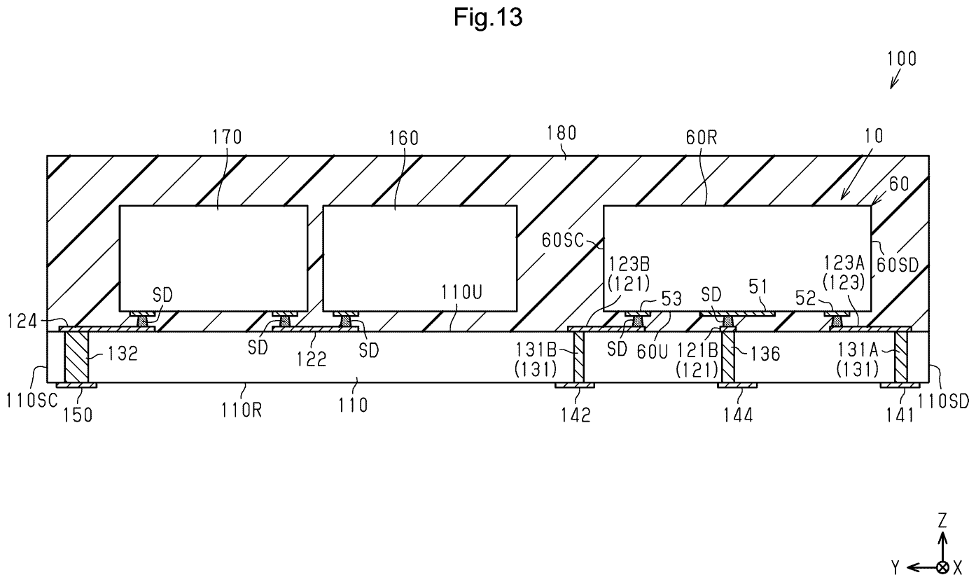

An example of the structure of a semiconductor module 100 including the semiconductor device 10 will now be described. FIG. 10 is a plan view showing a schematic internal configuration of the semiconductor module 100. FIG. 11 is an enlarged view of the semiconductor device 10 shown in FIG. 10. FIG. 12 is a bottom view of the semiconductor module 100. FIG. 13 is a cross-sectional view showing a schematic cross-sectional structure of the semiconductor module 100 taken along line F13-F13 of FIG. 10. FIG. 10 does not show a second encapsulation resin 180, which will be described later, to facilitate understanding of the drawing.

As shown in FIG. 10, the semiconductor module 100 includes a support substrate 110, a drive chip 160 electrically connected to the semiconductor device 10, and a control chip 170 electrically connected to the drive chip 160. The semiconductor device 10, the drive chip 160, and the control chip 170 are arranged on the support substrate 110. The semiconductor module 100 includes a second encapsulation resin 180 (refer to FIG. 13) encapsulating the semiconductor device 10, the drive chip 160, and the control chip 170.

The support substrate 110 has the form of a rectangular plate having a thickness in the Z-direction. In an example, the support substrate 110 is rectangular so that the long sides extend in the X-direction and the short sides extend in the Y-direction. The support substrate 110 has a support substrate front surface 110U and a support substrate back surface 110R facing opposite directions in the Z-direction, and first to fourth support substrate side surfaces 110SA to 110SD connecting the support substrate front surface 110U and the support substrate back surface 110R.

The semiconductor device 10, the drive chip 160, and the control chip 170 are arranged at the side of the support substrate front surface 110U. The semiconductor module 100 is mounted on the support substrate back surface 110R. That is, the semiconductor module 100 has a package structure of a surface mount type. The first support substrate side surface 110SA and the second support substrate side surface 110SB define two end surfaces of the support substrate 110 in the X-direction. The third support substrate side surface 110SC and the fourth support substrate side surface 110SD define two end surfaces of the support substrate 110 in the Y-direction.

The semiconductor device 10, the drive chip 160, and the control chip 170 are spaced apart from each other in the Y-direction. In plan view, the semiconductor device 10 is arranged closer to the fourth support substrate side surface 110SD than the drive chip 160 and the control chip 170 are. In plan view, the control chip 170 is arranged closer to the third support substrate side surface 110SC than the semiconductor device 10 and the drive chip 160 are. The drive chip 160 is arranged between the semiconductor device 10 and the control chip 170 in the Y-direction. In the example shown in FIG. 10, the drive chip 160 is arranged closer, in the Y-direction, to the control chip 170 than to the semiconductor device 10. In a plan view, the semiconductor device 10 is arranged so that the long sides of the semiconductor device 10 and the long sides of the support substrate 110 extend in the same direction and the short sides of the semiconductor device 10 and the short sides of the support substrate 110 extend in the same direction. As shown in FIG. 13, the semiconductor device 10 is arranged so that the encapsulation front surface 60U faces the support substrate front surface 110U.

As shown in FIG. 10, the support substrate 110 includes a first interconnect 121 and a second interconnect 122 arranged on the support substrate 110. The first interconnect 121 and the second interconnect 122 are formed on the support substrate front surface 110U.

The first interconnect 121 electrically connects the drive chip 160 and the semiconductor device 10. The second interconnect 122 electrically connects the control chip 170 and the drive chip 160. In an example, multiple first interconnects 121 and multiple second interconnects 122 are arranged.

As shown in FIG. 11, the first interconnects 121 include a gate interconnect 121A and an output interconnect 121B. The gate interconnect 121A is configured to individually electrically connect the drive chip 160 to the first gate wiring layers 54 and the second gate wiring layers 55 of the semiconductor device 10. Multiple (in the present embodiment, six) gate interconnects 121A are arranged in accordance with the total number of the first gate wiring layers 54 and the second gate wiring layers 55. The output interconnect 121B is configured to individually electrically connect the drive chip 160 to the interconnect layers 51 of the semiconductor device 10. Multiple (in the present embodiment, three) output interconnects 121B are arranged in accordance with the number of interconnect layers 51.

As shown in FIG. 12, the semiconductor module 100 includes multiple (in the present embodiment, two) drive terminals 141 and 142, multiple (in the present embodiment, three) output terminals 143 to 145, and multiple (in the present embodiment, three) boot terminals 146 to 148. Further, the semiconductor module 100 includes multiple (in the present embodiment, twelve) control terminals 150. The drive terminals 141 and 142, the output terminals 143 to 145, the boot terminals 146 to 148, and the control terminals 150 are formed on the support substrate back surface 110R.

The drive terminals 141 and 142 are configured to supply a current to the semiconductor device 10 and are arranged at opposite sides of the semiconductor device 10 in the Y-direction in plan view. Each of the drive terminals 141 and 142 is strip-shaped and extends in the X-direction in plan view. In an example, the drive terminals 141 and 142 are each greater than the semiconductor device 10 in length-wise dimension (dimension in the X-direction).

The drive terminal 141 is electrically connected to the drain wiring layers 52 of the GaN units 20A, 20C, and 20E of the semiconductor device 10. The drive terminal 141 is arranged on one of opposite ends of the support substrate back surface 110R located closer to the fourth support substrate side surface 110SD in the Y-direction.

The drive terminal 142 is electrically connected to the source wiring layers 53 of the GaN units 20B, 20D, and 20F of the semiconductor device 10. The drive terminal 142 is arranged between the semiconductor device 10 and the drive chip 160 in the Y-direction in plan view.

As shown in FIG. 12, the output terminals 143 to 145 are configured to output a current from the semiconductor device 10 and are arranged between the drive terminals 141 and 142 in the Y-direction in plan view. The output terminals 143 to 145 are arranged to overlap the semiconductor device 10 in plan view. The output terminals 143 to 145 are aligned with each other in the Y-direction and spaced apart from each other in the X-direction.

The output terminal 143 is used for the GaN units 20A and 20B (refer to FIG. 11) and is arranged to overlap the interconnect layer 51 corresponding to the GaN units 20A and 20B. The output terminal 143 is electrically connected to the interconnect layer 51 corresponding to the GaN units 20A and 20B.

The output terminal 144 is used for the GaN units 20C and 20D (refer to FIG. 11) and is arranged to overlap the interconnect layer 51 corresponding to the GaN units 20C and 20D. The output terminal 144 is electrically connected to the interconnect layer 51 corresponding to the GaN units 20C and 20D.

The output terminal 145 is used for the GaN units 20E and 20F (refer to FIG. 11) and is arranged to overlap the interconnect layer 51 corresponding to the GaN units 20E and 20F. The output terminal 145 is electrically connected to the interconnect layer 51 corresponding to the GaN units 20E and 20F.

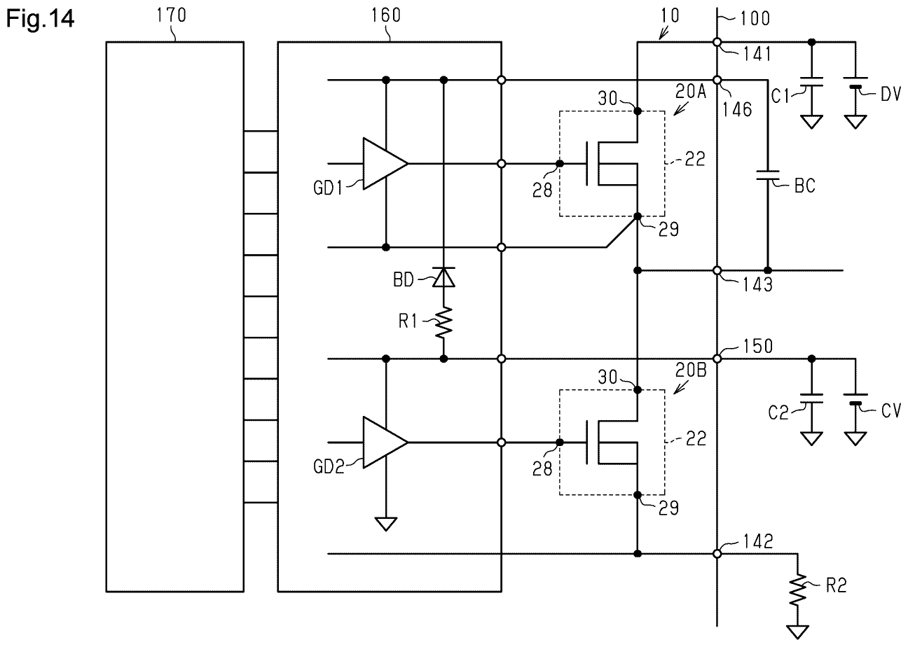

The boot terminals 146 to 148 are electrically connected to a boot diode BD (refer to FIG. 14) of a bootstrap circuit arranged on the drive chip 160. In plan view, the boot terminals 146 to 148 are arranged closer to the drive terminal 142 (drive chip 160) than the output terminals 143 to 145 are. The boot terminals 146 to 148 are aligned with each other in the Y-direction and spaced apart from each other in the X-direction. As viewed in the Y-direction, the boot terminals 146 to 148 are shifted from the output terminals 143 to 145.

The control terminals 150 are configured to be electrically connected to the control chip 170. The control terminals 150 are arranged on one of opposite ends of the support substrate back surface 110R located closer to the third support substrate side surface 110SC in the Y-direction. In plan view, the control terminals 150 are arranged closer to the third support substrate side surface 110SC than the control chip 170 is. The control terminals 150 are aligned with each other in the Y-direction and spaced apart from each other in the X-direction.

As shown in FIGS. 10 and 11, the semiconductor module 100 includes a drive interconnect 123, a control interconnect 124, a boot interconnect 125, a first terminal interconnect 126, and a second terminal interconnect 127. The drive interconnect 123, the control interconnect 124, the boot interconnect 125, the first terminal interconnect 126, and the second terminal interconnect 127 are arranged on the support substrate front surface 110U.

The semiconductor module 100 further includes a drive through interconnect 131, a control through interconnect 132, a boot through interconnect 133, a first terminal through interconnect 134, a second terminal through interconnect 135, and an output through interconnect 136. The drive through interconnect 131, the control through interconnect 132, the boot through interconnect 133, the first terminal through interconnect 134, the second terminal through interconnect 135, and the output through interconnect 136 extend through the support substrate 110 in the Z-direction. In an example, each of the control through interconnect 132, the boot through interconnect 133, the first terminal through interconnect 134, the second terminal through interconnect 135, and the output through interconnect 136 is a via.

The drive interconnect 123 is electrically connected to the semiconductor device 10. The drive interconnect 123 includes a first drive interconnect 123A and a second drive interconnect 123B.

The first drive interconnect 123A is configured to electrically connect the semiconductor device 10 and the drive terminal 141. Multiple (in the present embodiment, three) first drive interconnects 123A are arranged. The first drive interconnects 123A are individually electrically connected to the drain wiring layers 52 of the GaN units 20A, 20C, and 20E. The first drive interconnects 123A partially overlap the drive terminal 141 in plan view.

The second drive interconnect 123B is configured to electrically connect the semiconductor device 10 and the drive terminal 142. Multiple (in the present embodiment, three) second drive interconnects 123B are arranged. The second drive interconnects 123B are individually electrically connected to the source wiring layers 53 of the GaN units 20B, 20D, 20F. The second drive interconnects 123B partially overlap the drive terminal 142 in plan view.

The drive through interconnect 131 electrically connects the drive interconnect 123 and the drive terminals 141 and 142. The drive through interconnect 131 includes a first drive through interconnect 131A and a second drive through interconnect 131B.

The first drive through interconnect 131A electrically connects the first drive interconnect 123A and the drive terminal 141. Multiple (in the present embodiment, three) first drive through interconnects 131A are arranged in accordance with the number of first drive interconnects 123A. The first drive through interconnects 131A are arranged to overlap the first drive interconnects 123A and the drive terminal 141 in plan view.

The second drive through interconnect 131B electrically connects the second drive interconnect 123B and the drive terminal 142. Multiple (in the present embodiment, three) second drive through interconnects 131B are arranged in accordance with the number of second drive interconnects 123B. The second drive through interconnects 131B are arranged to overlap the second drive interconnects 123B and the drive terminal 142 in plan view.

As shown in FIG. 10, multiple (in the present embodiment, twelve) control interconnects 124 are arranged to be electrically connected to the control chip 170. In an example, the control interconnects 124 are arranged in accordance with the number of the control terminals 150. The control interconnects 124 individually partially overlap the control terminals 150 in plan view.

The control through interconnect 132 individually electrically connects the control interconnects 124 and the control terminals 150. Multiple (in the present embodiment, twelve) control through interconnects 132 are arranged in accordance with the number of control terminals 150. The control through interconnects 132 are arranged to overlap the control terminals 150 and the control interconnects 124 corresponding to the control terminals 150 in plan view.

The boot interconnect 125 is configured to electrically connect the drive chip 160 and the boot terminals 146 to 148. Multiple (in the present embodiment, three) boot interconnects 125 are arranged in accordance with the number of boot terminals 146 to 148.

As shown in FIG. 11, the boot through interconnect 133 individually electrically connects the boot interconnects 125 and the boot terminals 146 to 148. Multiple (in the present embodiment, three) boot through interconnects 133 are arranged in accordance with the number of boot interconnects 125. The boot through interconnects 133 are arranged to overlap the boot terminals 146 to 148 and the boot interconnects 125 corresponding to the boot terminals 146 to 148 in plan view.

As shown in FIG. 10, the first terminal interconnect 126 electrically connects the drive chip 160 and the drive terminal 141. The first terminal interconnect 126 partially overlaps the drive terminal 141 in plan view.

As shown in FIG. 11, the first terminal through interconnect 134 electrically connects the first terminal interconnect 126 and the drive terminal 141. The first terminal through interconnect 134 is arranged to overlap the first terminal interconnect 126 and the drive terminal 141 in plan view.

As shown in FIG. 10, the second terminal interconnect 127 electrically connects the drive chip 160 and the drive terminal 142. The second terminal interconnect 127 partially overlaps the drive terminal 142 in plan view.

As shown in FIG. 11, the second terminal through interconnect 135 electrically connects the second terminal interconnect 127 and the drive terminal 142. The second terminal through interconnect 135 is arranged to overlap the second terminal interconnect 127 and the drive terminal 142 in plan view.

As shown in FIG. 13, the external wiring layer 50 of the semiconductor device 10 is individually electrically connected to the first interconnect 121 and the drive interconnect 123 by a conductive bonding material SD such as a solder paste. Thus, the semiconductor device 10 is spaced apart from the support substrate front surface 110U in the Z-direction.

The output through interconnect 136 individually electrically connects the output interconnects 121B and the output terminals 143 to 145. Multiple (in the present embodiment, three) output through interconnects 136 are arranged in accordance with the number of the output interconnects 121B. The output through interconnects 136 are arranged to overlap the output terminals 143 to 145 and the output interconnects 121B corresponding to the output terminals 143 to 145 in plan view.

The second encapsulation resin 180 is arranged on the support substrate 110. The second encapsulation resin 180 has the form of a rectangular plate. The second encapsulation resin 180 includes four encapsulation side surfaces flush with the first to fourth support substrate side surfaces 110SA to 110SD of the support substrate 110. The second encapsulation resin 180 fills the gap between the semiconductor device 10 and the support substrate front surface 110U in the Z-direction. Thus, for example, the external wiring layer 50 of the semiconductor device 10 is insulated from the boot interconnect 125. In addition, for example, the external wiring layer 50 of the semiconductor device 10 is insulated from portions of the first interconnect 121 and the drive interconnect 123 that are free of the conductive bonding material SD.

### Circuit Configuration of Semiconductor Module

The circuit configuration of the semiconductor module 100 will now be described. FIG. 14 shows a schematic circuit configuration related to the GaN units 20A and 20B of the semiconductor device 10 in the semiconductor module 100. In the semiconductor module 100, the circuit configuration related to the GaN units 20C and 20D and the circuit configuration related to the GaN units 20E and 20F are the same as the circuit configuration related to the GaN units 20A and 20B, and thus will not be described in detail.

The drive chip 160 includes a driver circuit GD1 that drives the GaN transistor 22 of the GaN unit 20A, a driver circuit GD2 that drives the GaN transistor 22 of the GaN unit 20B, and a boot diode BD and a resistor R1 of the bootstrap circuit. The bootstrap circuit includes a boot capacitor BC arranged outside the semiconductor module 100.

The boot capacitor BC is electrically connected to the boot terminal 146 and the output terminal 143. More specifically, the boot capacitor BC includes a first electrode electrically connected to the boot terminal 146 and a second electrode electrically connected to the output terminal 143. The cathode of the boot diode BD is electrically connected to the boot terminal 146. The anode of the boot diode BD is electrically connected to a first end of the resistor R1. The resistor R1 has a second end electrically connected to a power terminal (VCC) assigned to one of the control terminals 150. The drive terminal 141 is electrically connected to a drive power supply DV arranged outside the semiconductor module 100. A capacitor C1 is arranged on a conductive path connecting the drive terminal 141 and the positive terminal of the drive power supply DV and is connected in parallel to the drive power supply DV. The negative terminal of the drive power supply DV and the capacitor C1 are connected to ground. The drive terminal 142 is connected to ground via a resistor R2. The control terminal 150 (power supply terminal VCC) is electrically connected to a control power supply CV arranged outside the semiconductor module 100. A capacitor C2 is arranged on a conductive path connecting the control terminal 150 and the positive terminal of the control power supply CV and is connected in parallel to the control power supply CV. The negative terminal of the control power supply CV and the capacitor C2 are connected to ground.

The driver circuit GD1 is electrically connected to the gate electrode 28 of the GaN transistor 22 in the GaN unit 20A. The driver circuit GD1 provides a gate control signal to the gate electrode 28 for driving the GaN transistor 22 of the GaN unit 20A. The driver circuit GD1 includes a low-potential power supply terminal that is electrically connected to the source electrode 29 of the GaN transistor 22 in the GaN unit 20A. The driver circuit GD1 includes a high-potential power supply terminal that is electrically connected to the boot terminal 146 and the cathode of the boot diode BD.

The driver circuit GD2 is electrically connected to the gate electrode 28 of the GaN transistor 22 in the GaN unit 20B. The driver circuit GD2 provides a gate control signal to the gate electrode 28 for driving the GaN transistor 22 of the GaN unit 20B. The driver circuit GD2 includes a high-potential power supply terminal that is electrically connected to the second end of the resistor R1 and the control terminal 150 (power supply terminal VCC). The driver circuit GD2 includes a low-potential power supply terminal that is connected to ground.

The control chip 170 receives a signal from the outside of the semiconductor module 100. Based on the received signal, the control chip 170 outputs a signal for generating a gate control signal in the driver circuits GD1 and GD2 to the driver circuits GD1 and GD2.

### Method for Manufacturing Semiconductor Device

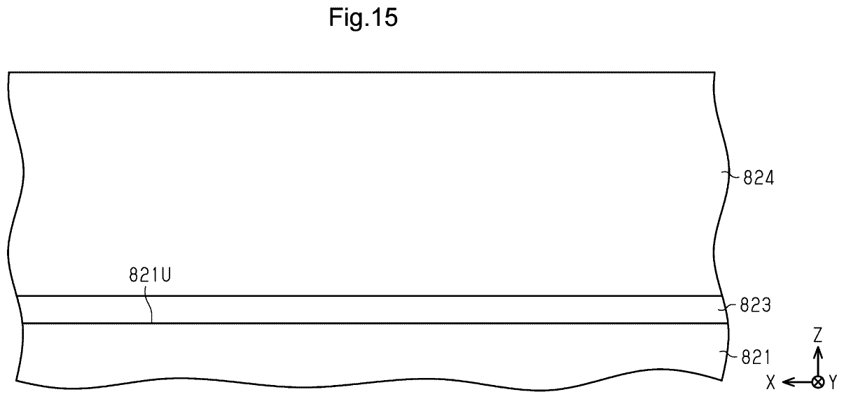

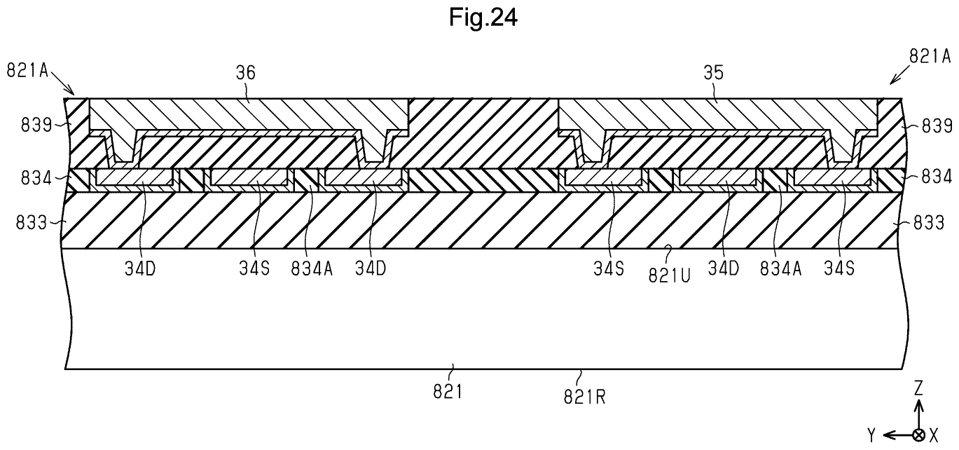

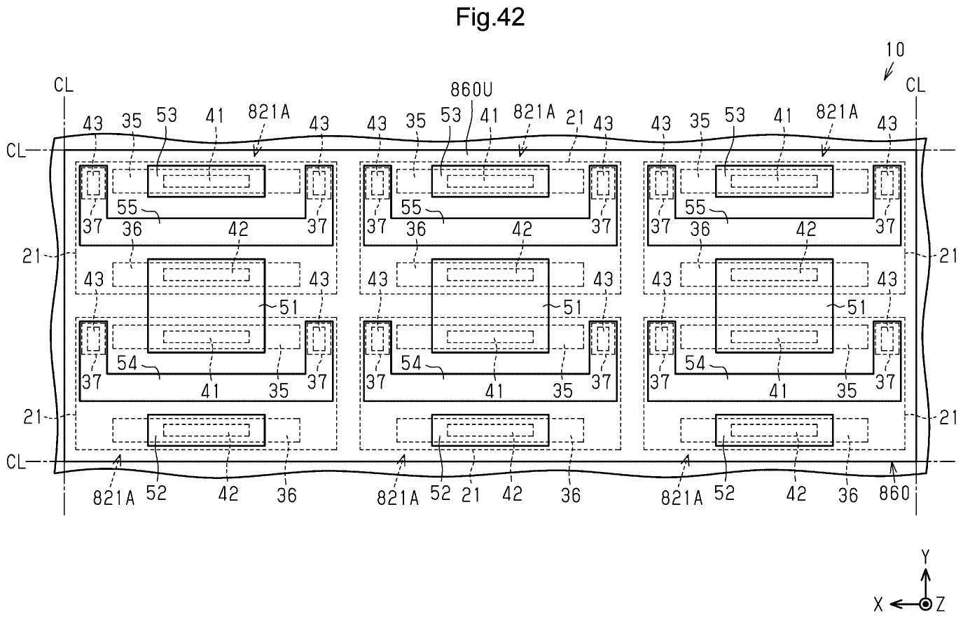

An example of a method for manufacturing the semiconductor device 10 will now be described with reference to FIGS. 15 to 42. FIGS. 15 to 42 are schematic cross-sectional views illustrating exemplary manufacturing steps of the semiconductor device 10. FIGS. 24 to 41 are schematic cross-sectional views of the GaN units 20A and 20B. The GaN units 20C to 20F are the same as the GaN units 20A and 20B and thus will not be described in detail. FIG. 42 shows a planar structure of a portion of a wafer 821, which will be described later.

As shown in FIG. 15, a method for manufacturing the semiconductor device 10 includes preparing a wafer 821. The wafer 821 has the form of a flat plate having a thickness in the Z-direction. The wafer 821 includes a wafer front surface 821U and a wafer back surface 821R (refer to FIG. 24) that face opposite directions in the Z-direction. The wafer 821 includes the substrate 21. In practice, the wafer 821 is sized to allow for the formation of dozens or hundreds of substrates 21. The wafer 821 is, for example, a Si wafer.

The wafer 821 includes multiple chip formation regions 821A (refer to FIG. 24) in which the GaN transistors 22 are formed at the side of the wafer front surface 821U (a wafer front surface side). An example of a method of manufacturing the GaN transistor 22 will be described with reference to FIGS. 15 to 23.

As shown in FIG. 15, a buffer layer 823 is formed on the wafer 821. Then, an electron transit layer 824 is formed on the buffer layer 823. The buffer layer 823 and the electron transit layer 824 may undergo epitaxial growth through a metal organic chemical vapor deposition (MOCVD) process.

Although not shown in detail, in an example, the buffer layer 823 may be a multilayer buffer layer. The multilayer buffer layer may include an AlN layer (first buffer layer) formed on the wafer 821 and a graded AlGaN layer (second buffer layer) formed on the AlN layer. The graded AlGaN layer may be formed, for example, by stacking three AlGaN layers having Al compositions of 75%, 50%, and 25% in the order from the side of the AlN layer. The electron transit layer 824 formed on the buffer layer 823 may be a GaN layer.

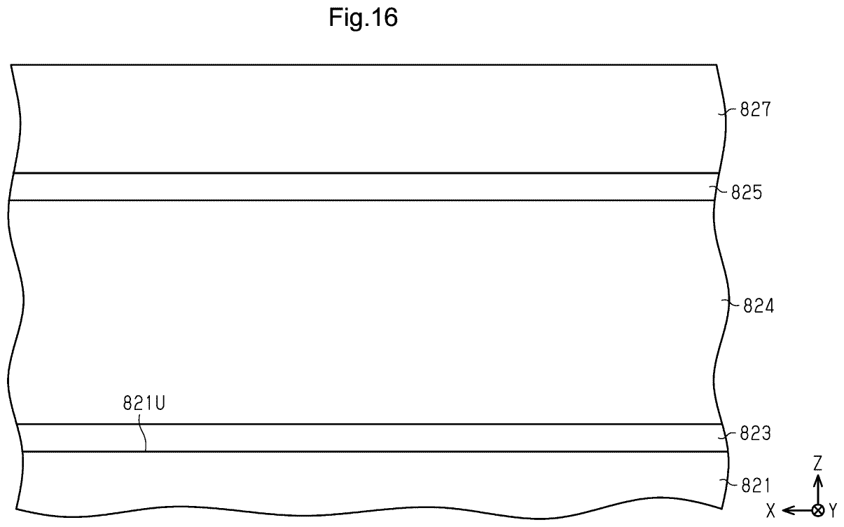

Subsequently, as shown in FIG. 16, an electron supply layer 825 is composed of a nitride semiconductor and is formed on the electron transit layer 824. Then, a nitride semiconductor layer 827 is formed on the electron supply layer 825. The electron transit layer 824 and the nitride semiconductor layer 827 may be epitaxially grown through the MOCVD process.

The electron transit layer 824 may be a GaN layer, and the electron supply layer 825 may be an AlGaN layer. Thus, the nitride semiconductor forming the electron supply layer 825 has a larger band gap than the electron transit layer 824.

The nitride semiconductor layer 827 is formed from a nitride semiconductor containing an acceptor impurity. In an example, during growth of the nitride semiconductor layer 827, magnesium doping is applied to form the nitride semiconductor layer 827 containing an acceptor impurity. The nitride semiconductor layer 827 is composed of a nitride semiconductor having a smaller band gap than the electron supply layer 825. The nitride semiconductor layer 827 forms the gate layer 27 (refer to FIG. 5).

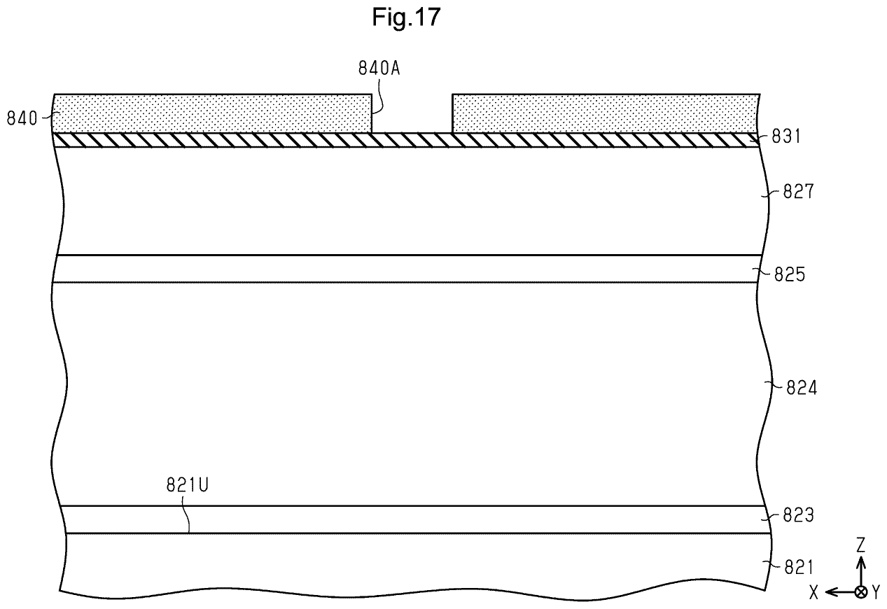

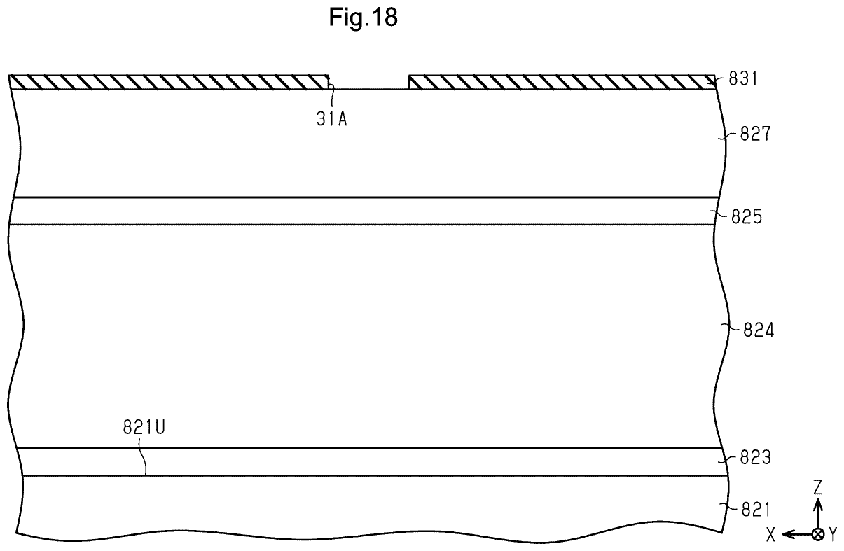

Subsequently, as shown in FIGS. 17 and 18, a first insulation film 831 is formed. As shown in FIG. 17, the first insulation film 831 is formed on the nitride semiconductor layer 827 through, for example, a low-pressure chemical vapor deposition (LPCVD) process. The first insulation film 831 is formed, for example, on the entire upper surface of the nitride semiconductor layer 827. The first insulation film 831 forms the first insulation film 31 (refer to FIG. 5) and may be formed from, for example, at least one of Si₃N₄, SiO₂, SiON, Al₂O₃, AlN, and AlON. In an example, the first insulation film 831 is formed from Si₃N₄.

Subsequently, a photoresist mask 840 is formed on the first insulation film 831. The photoresist mask 840 has an opening 840A that exposes a portion of the upper surface of the first insulation film 831. The opening 840A is formed by selectively removing the photoresist mask 840 through lithography and etching.

Subsequently, as shown in FIG. 18, the first insulation film 831 exposed in the opening 840A is removed through etching using the photoresist mask 840. Thus, the opening 31A is formed in the first insulation film 831. An example of the etching is dry etching.

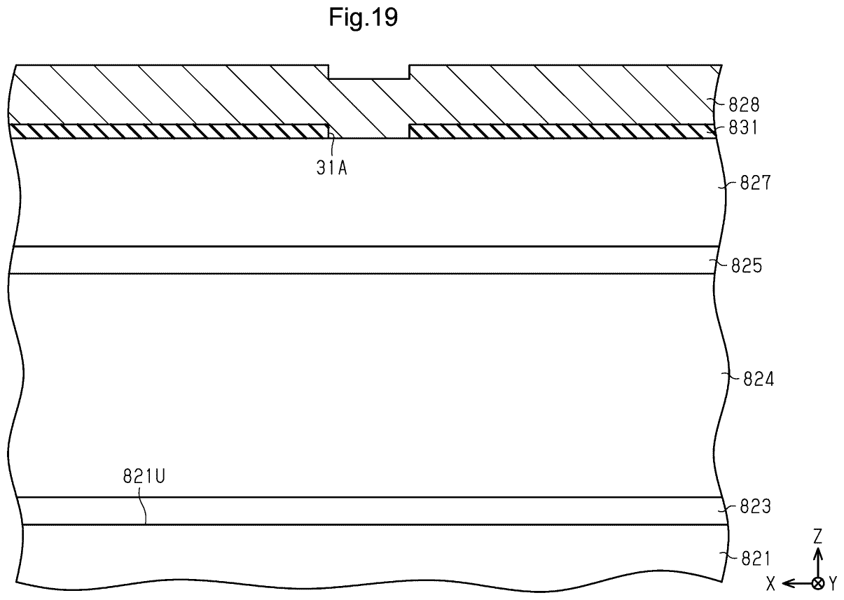

Subsequently, as shown in FIG. 19, an electrode layer 828 is formed and connected to the nitride semiconductor layer 827 through the opening 31A. The electrode layer 828 forms the gate electrode 28 and is, for example, a TiN layer. The electrode layer 828 is formed by, for example, sputtering. The electrode layer 828 fills the opening 31A and is formed on the entire upper surface of the first insulation film 831.

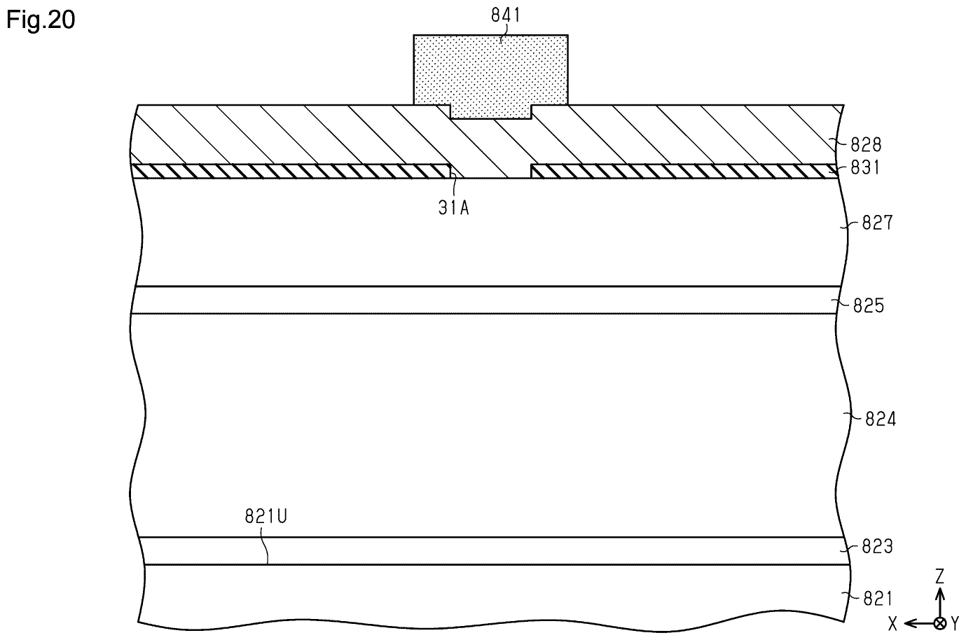

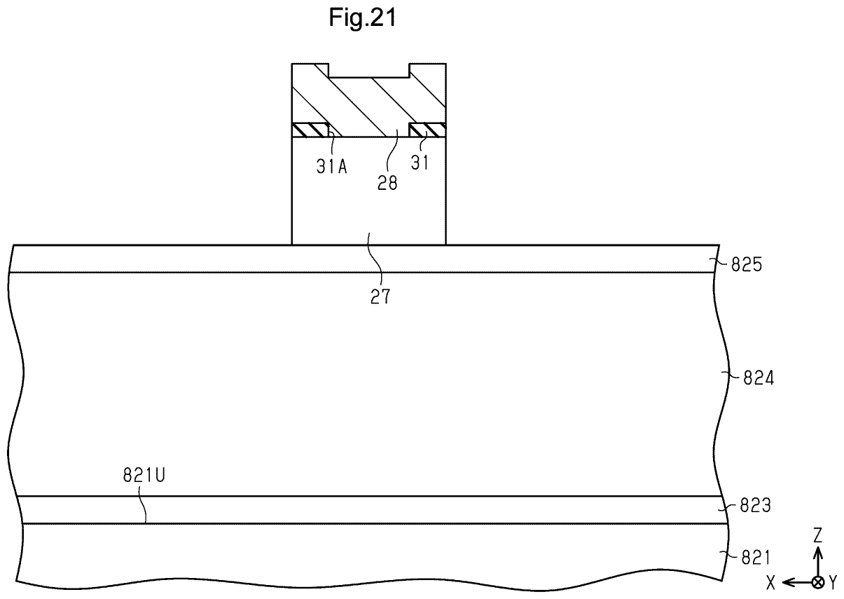

Subsequently, as shown in FIGS. 20 and 21, the nitride semiconductor layer 827, the first insulation film 831, and the electrode layer 828 are etched to form the gate layer 27, the first insulation film 31, and the gate electrode 28.

More specifically, as shown in FIG. 20, a resist mask 841 is formed on the electrode layer 828. The resist mask 841 is formed on a portion of the upper surface of the electrode layer 828. Subsequently, as shown in FIG. 21, the nitride semiconductor layer 827, the first insulation film 831, and the electrode layer 828 are removed through etching using the resist mask 841. As a result, the gate layer 27 is formed from the nitride semiconductor layer 827. The gate electrode 28 is formed from the electrode layer 828. The first insulation film 31 is formed from the first insulation film 831. An example of the etching is dry etching.

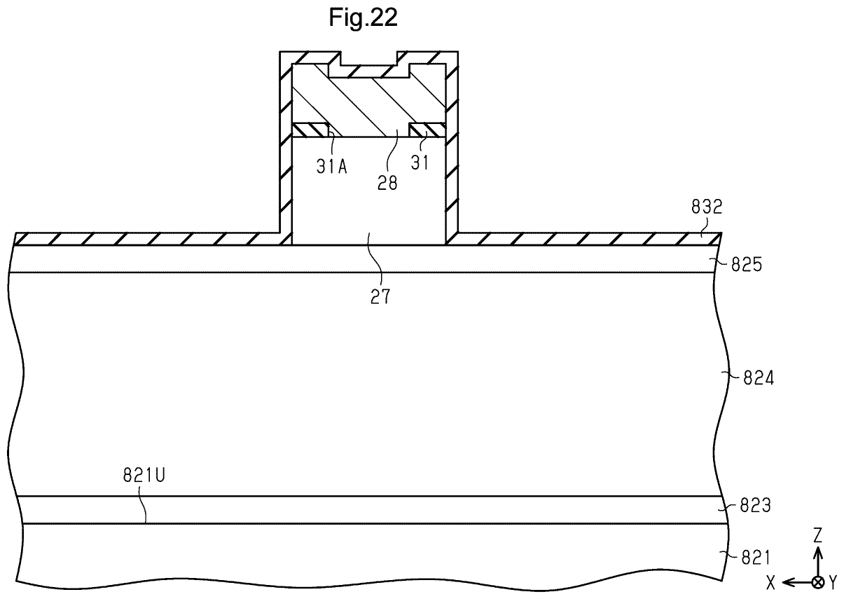

Subsequently, as shown in FIG. 22, a second insulation film 832 is formed to cover the electron supply layer 825, the gate layer 27, the first insulation film 31, and the gate electrode 28. The second insulation film 832 forms the second insulation film 32 and is formed by, for example, LPCVD. The second insulation film 832 may be formed from at least one of Si₃N₄, SiO₂, SiON, Al₂O₃, AlN, and AlON. In an example, the second insulation film 832 is formed from Si₃N₄. In other words, the second insulation film 832 is formed from the same material as the first insulation film 831. The second insulation film 832 and the first insulation film 831 may each be formed from a different material.

Then, a first opening 32A and a second opening 32B extending through the second insulation film 832 are formed to expose the electron supply layer 825. The first opening 32A and the second opening 32B are formed so that the gate layer 27 is arranged between the first opening 32A and the second opening 32B. The gate layer 27 may be arranged closer to the first opening 32A than to the second opening 32B. The first opening 32A and the second opening 32B are formed by, for example, etching.

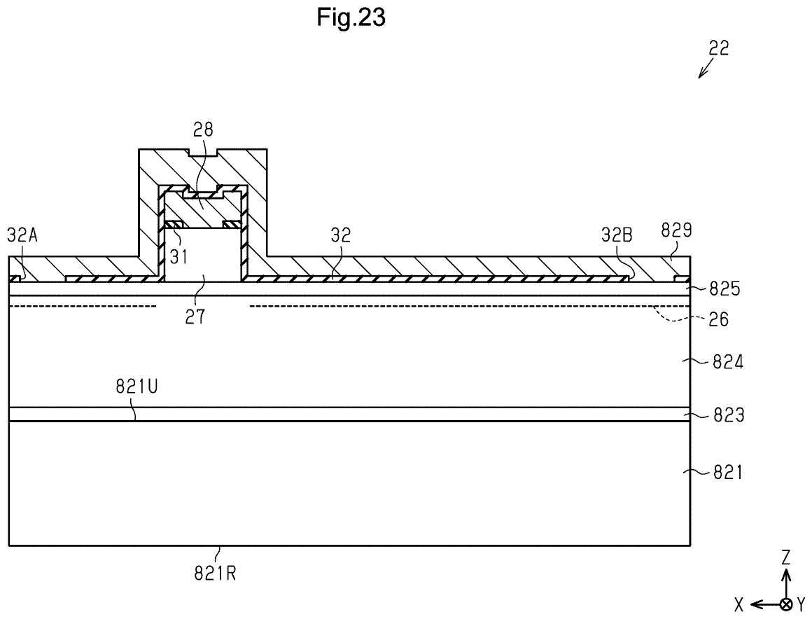

Subsequently, as shown in FIG. 23, the source electrode 29 and the drain electrode 30 (refer to FIG. 5) are formed so as to be in contact with the electron supply layer 825.

In this step, first, a metal layer 829 is formed on the second insulation film 832. The metal layer 829 is formed on the entire upper surface of the second insulation film 832. The metal layer 829 fills the first opening 32A and the second opening 32B and is in contact with the electron supply layer 825 through the first opening 32A and the second opening 32B. In an example, the metal layer 829 may include at least one of a Ti layer, a TiN layer, an A1 layer, an AlSiCu layer, and an AlCu layer. The metal layer 829 is then selectively removed through lithography and etching. This forms the source electrode 29 and the drain electrode 30 shown in FIG. 5.

Subsequently, as shown in FIG. 24, a third insulation film 833 is formed on the second insulation film 832 (refer to FIG. 23), and then a wiring layer 834 is formed on the third insulation film 833. Then, a fifth insulation film 839 is formed on the wiring layer 834. Next, the source pad 35, the drain pad 36, and the gate pad 37 (refer to FIG. 8) are formed on the fifth insulation film 839.

The third insulation film 833 forms the third insulation film 33 by, for example, LPCVD. In an example, the third insulation film 833 is formed from SiO₂. The third insulation film 833 is formed on the entire surface of the second insulation film 832.

Subsequently, a fourth insulation film 834A is formed on the third insulation film 833. The fourth insulation film 834A forms the fourth insulation film 34A by, for example, LPCVD. In an example, the fourth insulation film 834A is formed from one of Si₃N₄ and SiO₂. The fourth insulation film 834A includes multiple source wiring portions 34S, multiple drain wiring portions 34D, and multiple gate wiring portions 34G. More specifically, the fourth insulation film 834A is selectively removed through, for example, etching to form grooves for formation of the source wiring portions 34S, the drain wiring portions 34D, and the gate wiring portions 34G. The grooves are filled by, for example, an electrolytic plating process to form the source wiring portions 34S, the drain wiring portions 34D, and the gate wiring portions 34G. This forms the wiring layer 834.

Next, a fifth insulation film 839 is formed on the wiring layer 834 by, for example, LPCVD. The fifth insulation film 839 is formed, for example, on the entire upper surface of the wiring layer 834. In an example, the fifth insulation film 839 is formed from one of Si₃N₄ and SiO₂. The fifth insulation film 839 is selectively removed through, for example, etching to form grooves for formation of the source pad 35, the drain pad 36, and the gate pad 37. The grooves are filled by, for example, an electrolytic plating process to from the source pad 35, the drain pad 36, and the gate pad 37.

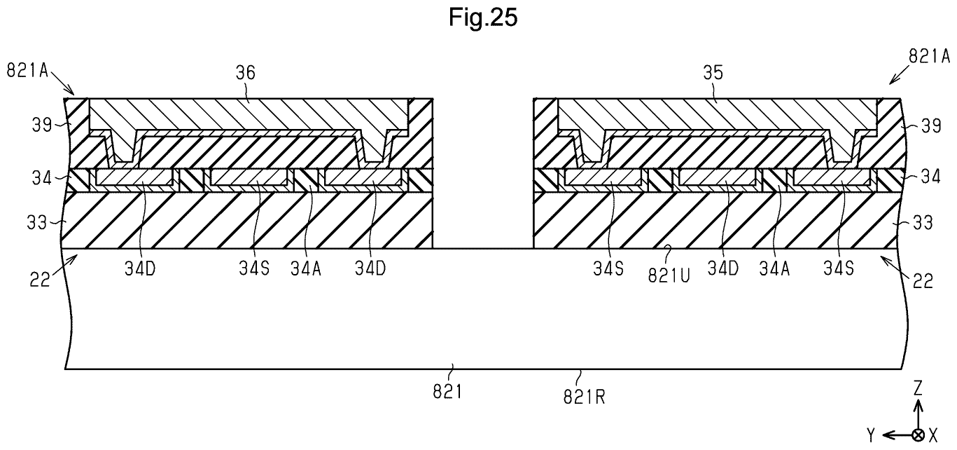

As shown in FIG. 25, for example, etching is performed to remove a portion between the adjacent GaN transistors 22 above the wafer 821. As a result, the fifth insulation film 39 is formed from the fifth insulation film 839, and the fourth insulation film 34A is formed from the fourth insulation film 834A. This forms the wiring layer 34 from the wiring layer 834. The third insulation film 33 is formed from the third insulation film 833. In addition, referring to FIG. 23, the second insulation film 32 is formed from the second insulation film 832, the electron supply layer 25 (refer to FIG. 5) is formed from the electron supply layer 825, the electron transit layer 24 (refer to FIG. 5) is formed from the electron transit layer 824, and the buffer layer 23 (refer to FIG. 5) is formed from the buffer layer 823. As described above, multiple chip formation regions 821A including the GaN transistors 22 are formed in the wafer 821. The steps described above prepare the wafer 821 including the multiple chip formation regions 821A in which the GaN transistors 22 are formed at the side of the wafer front surface 821U of the wafer 821.

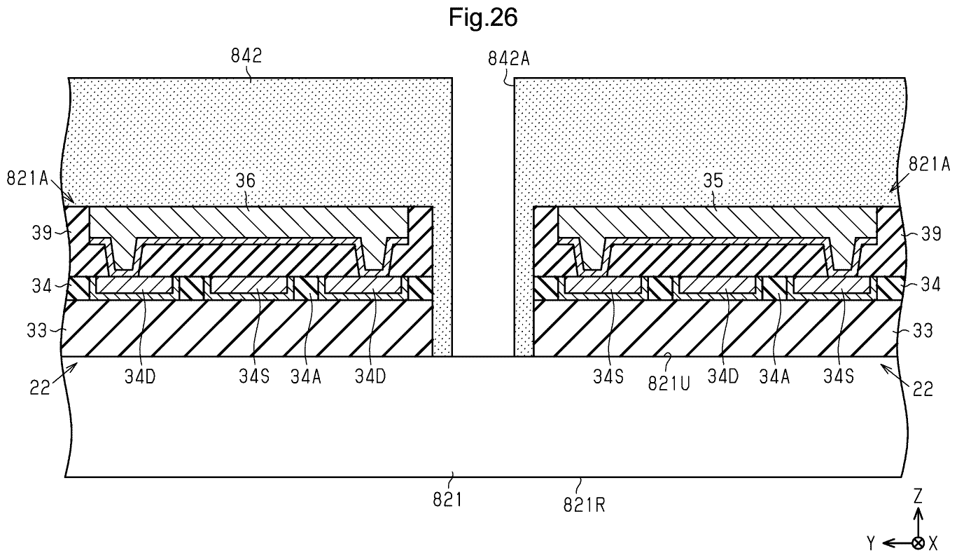

As shown in FIGS. 26 to 28, the method for manufacturing the semiconductor device 10 includes forming a groove 821B between adjacent ones of the chip formation regions 821A.

As shown in FIG. 26, a dry film resist 842 is formed on the fifth insulation film 39, the source pad 35, the drain pad 36, and the gate pad 37. The dry film resist 842 further covers a side surface of the fifth insulation film 839, a side surface of the fourth insulation film 34A of the wiring layer 34, and a side surface of the third insulation film 33. The dry film resist 842 has an opening 842A exposing the wafer 821. The opening 842A exposes the portion of the wafer 821 between adjacent ones of the chip formation regions 821A.

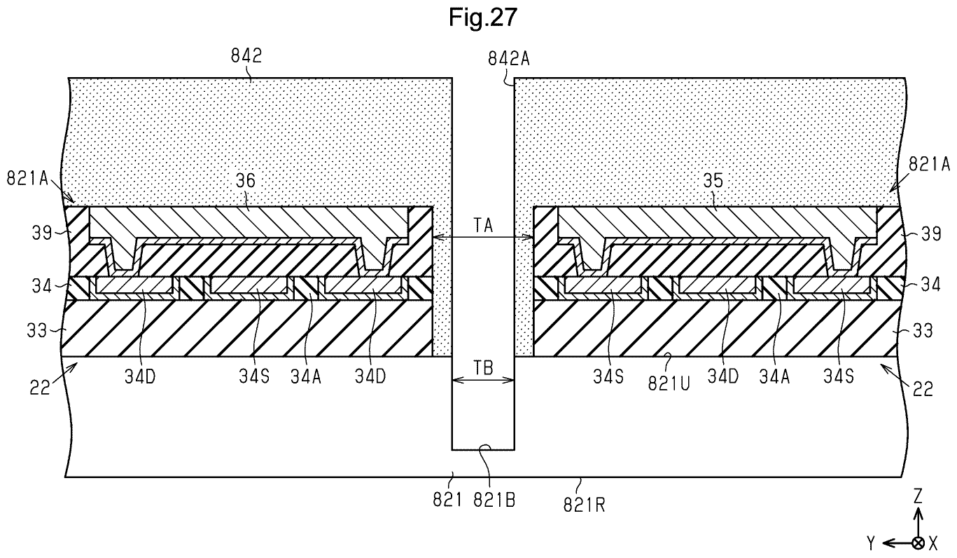

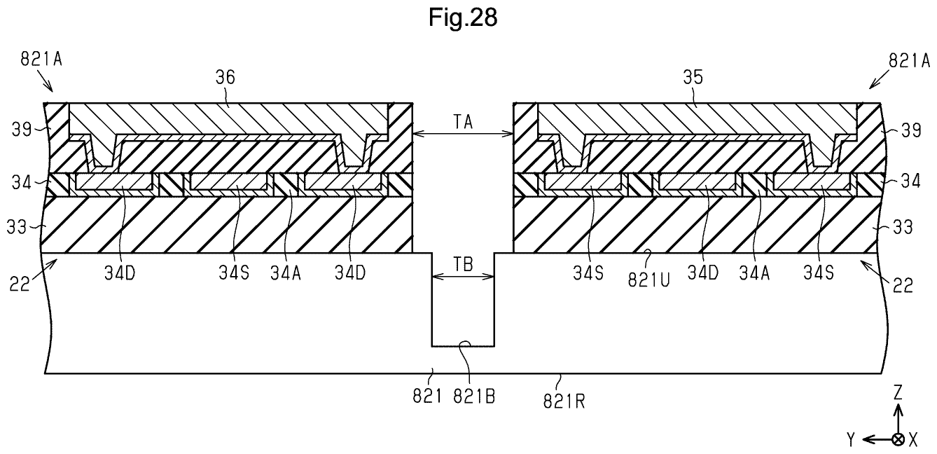

As shown in FIG. 27, dry etching using the dry film resist 842 is performed to remove a portion of the wafer 821 exposed from the opening 842A. This forms a groove 821B in the wafer 821. The groove 821B is formed between adjacent ones of the chip formation regions 821A of the wafer 821 in plan view. The groove 821B is formed so as to have a width-wise dimension TB that is smaller than a distances TA between the wiring layers 34 of the adjacent ones of the chip formation regions 821A. That is, forming the groove 821B between adjacent ones of the chip formation regions 821A is forming a groove 821B having the width-wise dimension TB smaller than the distance TA between the wiring layers 34 of the adjacent ones of the chip formation regions 821A. Subsequently, as shown in FIG. 28, the dry film resist 842 is removed. The width-wise dimension TB is equal to the distance DA shown in FIG. 4.

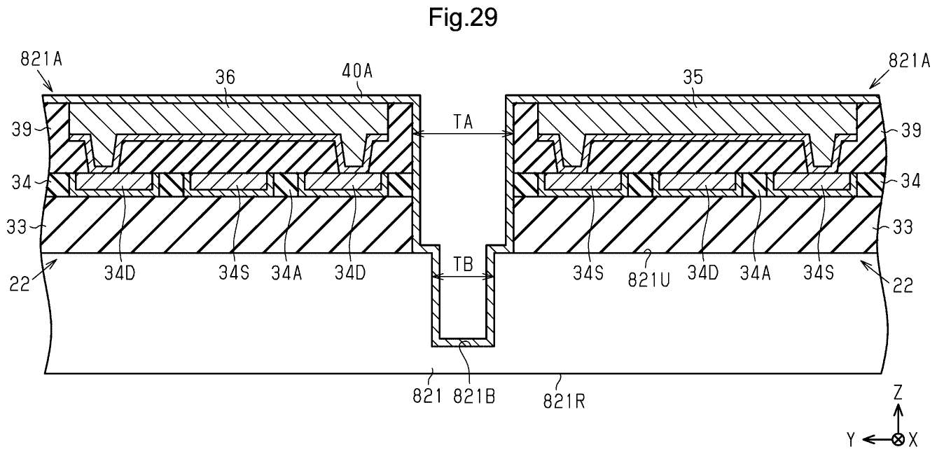

As shown in FIGS. 29 to 33, the method for manufacturing the semiconductor device 10 includes forming the posts 40 on the source pad 35, the drain pad 36, and the gate pad 37 (refer to FIG. 8) of each GaN transistor 22.

As shown in FIG. 29, a seed layer 40A is formed on the chip formation regions 821A, the exposed portion of the wafer front surface 821U, and the wall surface of the groove 821B. The seed layer 40A is, for example, a Ti layer.

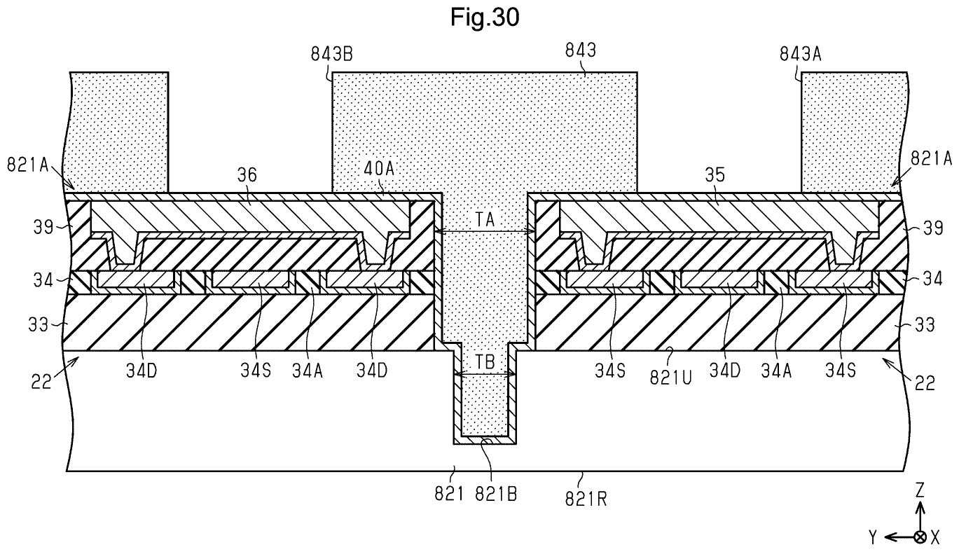

Subsequently, as shown in FIG. 30, a dry film resist 843 is formed on the seed layer 40A. The dry film resist 843 fills the gap between adjacent ones of the chip formation regions 821A including the groove 821B. In the example shown in FIG. 30, the dry film resist 843 has an opening 843A that partially exposes the region of the seed layer 40A corresponding to the source pad 35 of the GaN unit 20A and an opening 843B that partially exposes the region of the seed layer 40A corresponding to the drain pad 36 of the GaN unit 20B. Although not shown, the dry film resist 843 has openings that expose the regions of the seed layer 40A corresponding to the gate pads 37 of the GaN units 20A and 20B. The dry film resist 843 also has an opening that exposes the region of the seed layer 40A corresponding to the drain pad 36 of the GaN unit 20A and an opening that exposes the region of the seed layer 40A corresponding to the source pad 35 of the GaN unit 20B.

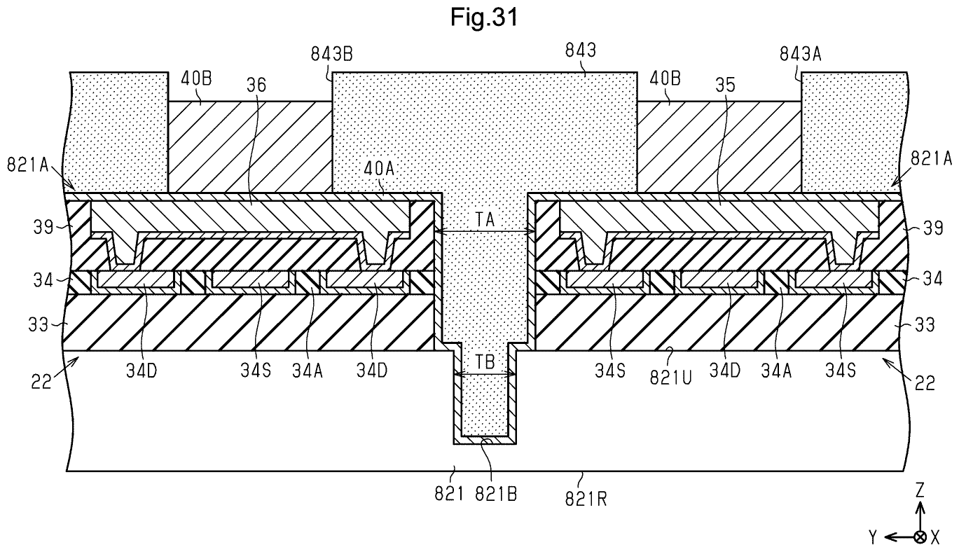

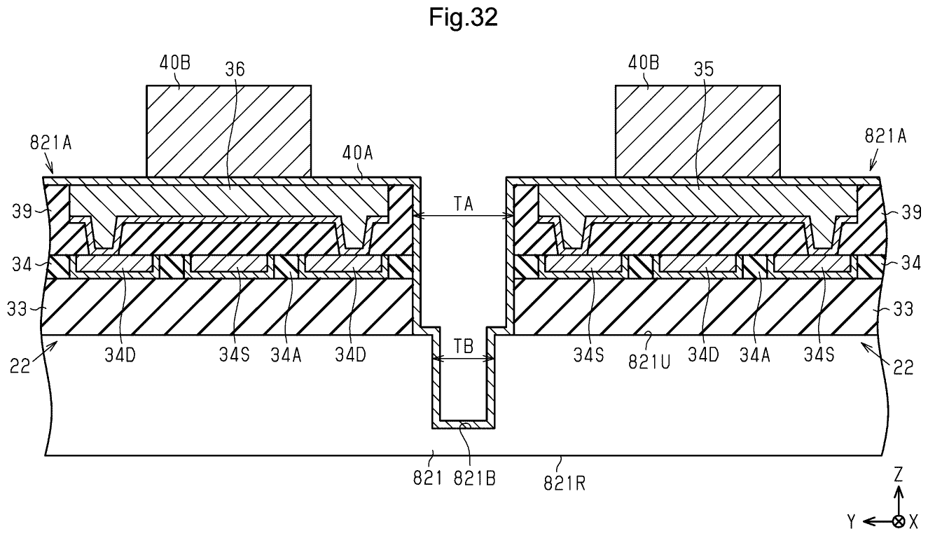

Subsequently, as shown in FIG. 31, a plating layer 40B is formed to fill the openings 843A and 843B of the dry film resist 843. The plating layer 40B is formed by, for example, electrolytic plating using the seed layer 40A as a conductive path. The plating layer 40B is, for example, a Cu layer. Next, as shown in FIG. 32, the dry film resist 843 is removed.

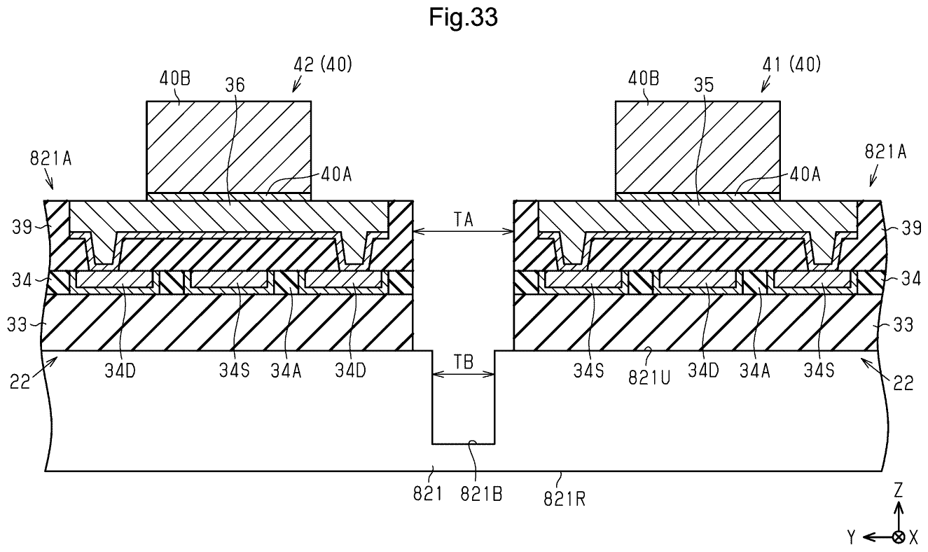

Subsequently, as shown in FIG. 33, the portion of the seed layer 40A exposed from the plating layer 40B is removed. The steps described above form the post 40 in each chip formation region 821A. In the example shown in FIG. 33, the source post 41 is formed on the source pad 35 of the GaN unit 20A. The drain post 42 is formed on the drain pad 36 of the GaN unit 20B. That is, forming the post 40 includes forming the source post 41 on the source pad 35 in one of two adjacent ones of the chip formation regions 821A and forming the drain post 42 on the drain pad 36 in the other one of the two adjacent ones of the chip formation regions 821A.

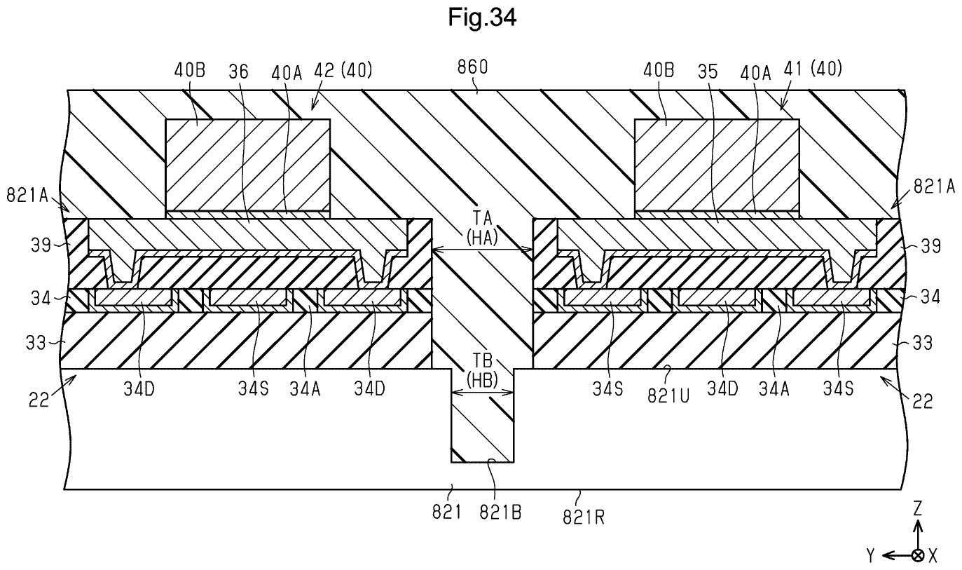

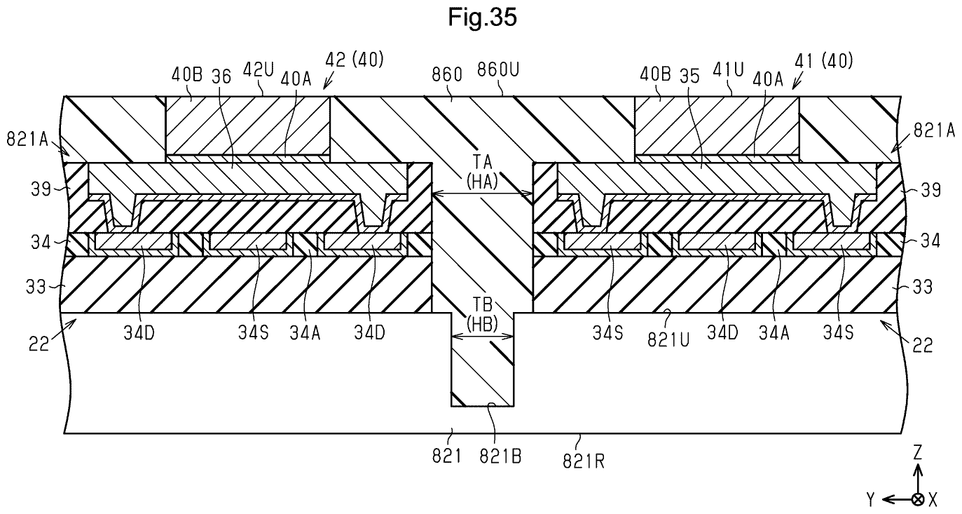

As shown in FIGS. 34 and 35, the method for manufacturing the semiconductor device 10 includes forming the resin layer 860 that fills the groove 821B and exposes the upper surface of the post 40 on the wafer 821.

As shown in FIG. 34, the resin layer 860 fills the groove 821B and the gap between adjacent ones of the chip formation regions 821A and covers the post 40. In the example shown in FIG. 34, the resin layer 860 covers the upper surface 41U of the source post 41 and the upper surface 42U of the drain post 42. The resin layer 860 is formed by transfer molding or compression molding. The resin layer 860 is, for example, a black epoxy resin. The resin layer 860 forms the first encapsulation resin 60.

The portion of the resin layer 860 filling the groove 821B corresponds to the substrate encapsulation layer 62 (refer to FIG. 7). The portion of the resin layer 860 filling the gap between adjacent ones of the chip formation regions 821A corresponds to the wiring encapsulation layer 61 (refer to FIG. 7). Thus, the dimension HB of the substrate encapsulation layer 62 corresponds to the width-wise dimension of the groove 821B. The dimension HA of the wiring encapsulation layer 61 corresponds to the distances TA between the chip formation regions 821A. The dimension HB of the substrate encapsulation layer 62 is smaller than the dimension HA of the wiring encapsulation layer 61.

Subsequently, as shown in FIG. 35, the upper surface 860U of the resin layer 860 and the upper surfaces of the posts 40 are polished so that the posts 40 are exposed from the upper surface 860U of the resin layer 860. As a result, the resin layer 860 and the posts 40 shown in FIG. 35 are smaller in thickness than the resin layer 860 and the posts 40 shown in FIG. 34. The upper surface 860U of the resin layer 860 corresponds to the encapsulation front surface 60U (refer to FIG. 7) of the first encapsulation resin 60.

In the example shown in FIG. 35, the upper surface 860U of the resin layer 860 is flush with the upper surface 41U of the source post 41 in the GaN unit 20A and the upper surface 42U of the drain post 42 in the GaN unit 20B. Although not shown, the upper surface 860U of the resin layer 860 is flush with the upper surface 42U of the drain post 42 and the upper surface 43U of the gate post 43 in the GaN unit 20A, and the upper surface 41U of the source post 41 and the upper surface 43U of the gate post 43 in the GaN unit 20B. Thus, the upper surface 860U of the resin layer 860 is flush with the upper surface of the post 40.

Thus, the forming the resin layer 860 that exposes the upper surface of the post 40 on the wafer 821 includes forming the resin layer 860 to fill the groove 821B and the gap between adjacent ones of the chip formation regions 821A and to cover the post 40, and polishing the upper surface 860U of the resin layer 860 and the upper surface of the post 40 to expose the post 40 from the upper surface 860U of the resin layer 860.

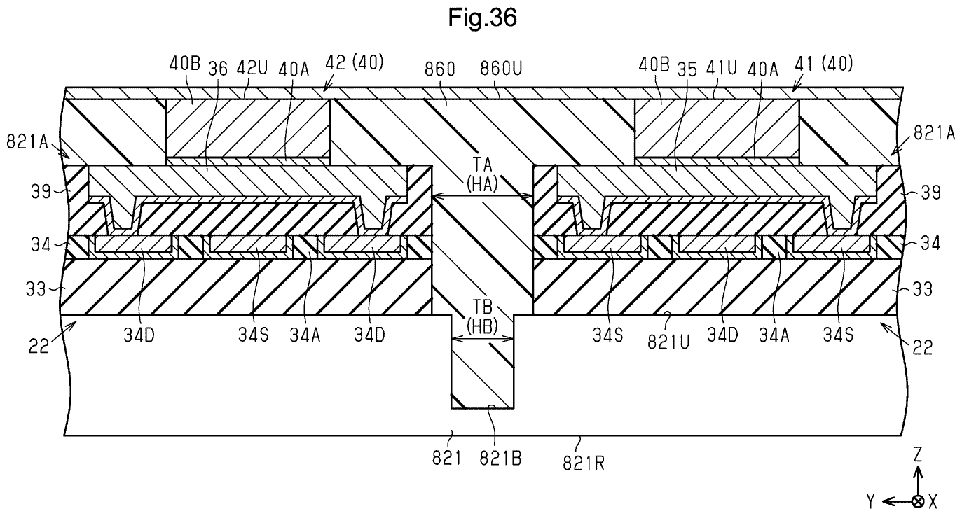

As shown in FIGS. 36 to 39, the method for manufacturing the semiconductor device 10 includes forming the external wiring layer 50.

As shown in FIG. 36, the seed layer 50A is formed on the upper surface 860U of the resin layer 860 and the upper surfaces of the posts 40. The seed layer 50A is, for example, a Ti layer.

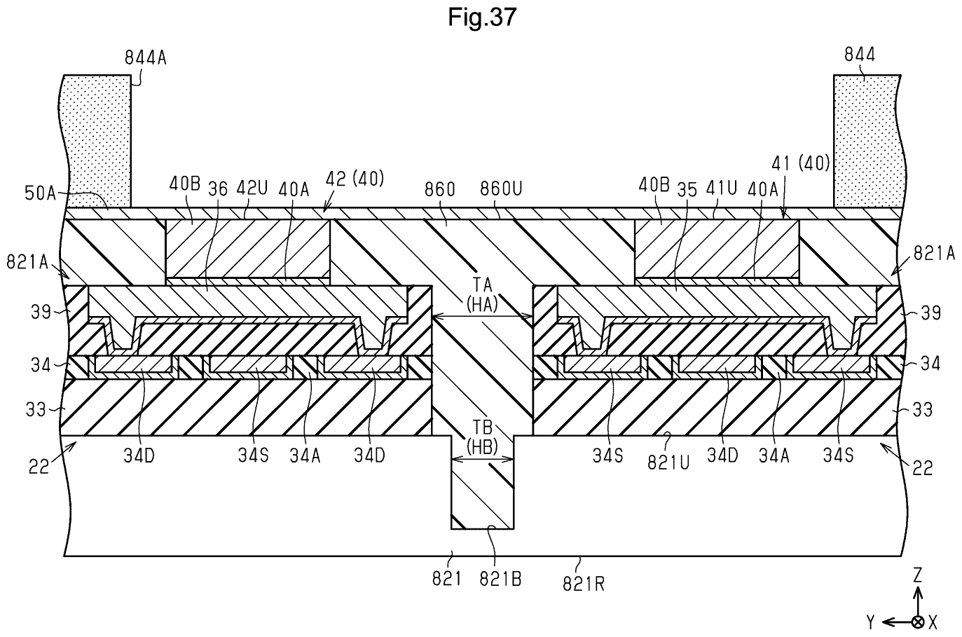

Subsequently, as shown in FIG. 37, a dry film resist 844 is formed on the seed layer 50A. In the example shown in FIG. 37, the dry film resist 844 has an opening 844A that exposes the portion of the seed layer 50A where the interconnect layer 51 (refer to FIG. 7) is formed. Although not shown, the dry film resist 844 has openings that expose the seed layer 50A where the drain wiring layer 52, the source wiring layer 53, the first gate wiring layer 54, and the second gate wiring layer 55 (refer to FIGS. 7 and 8) are formed.

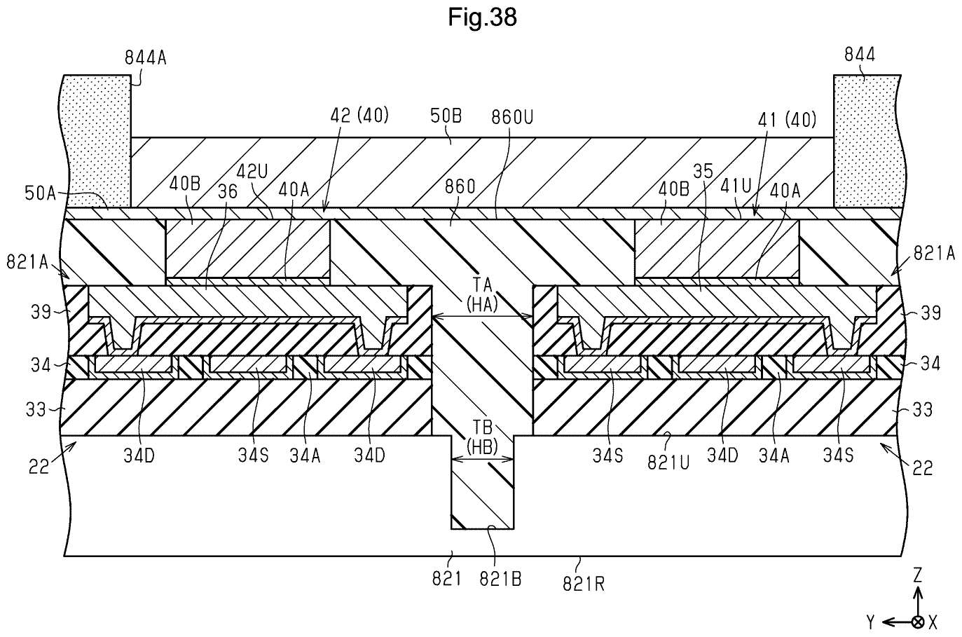

Subsequently, as shown in FIG. 38, a plating layer 50B is formed so as to fill the opening 844A of the dry film resist 844. The plating layer 50B is formed by, for example, electrolytic plating using the seed layer 50A as a conductive path. The plating layer 50B is, for example, a Cu layer. Then, the dry film resist 844 is removed.

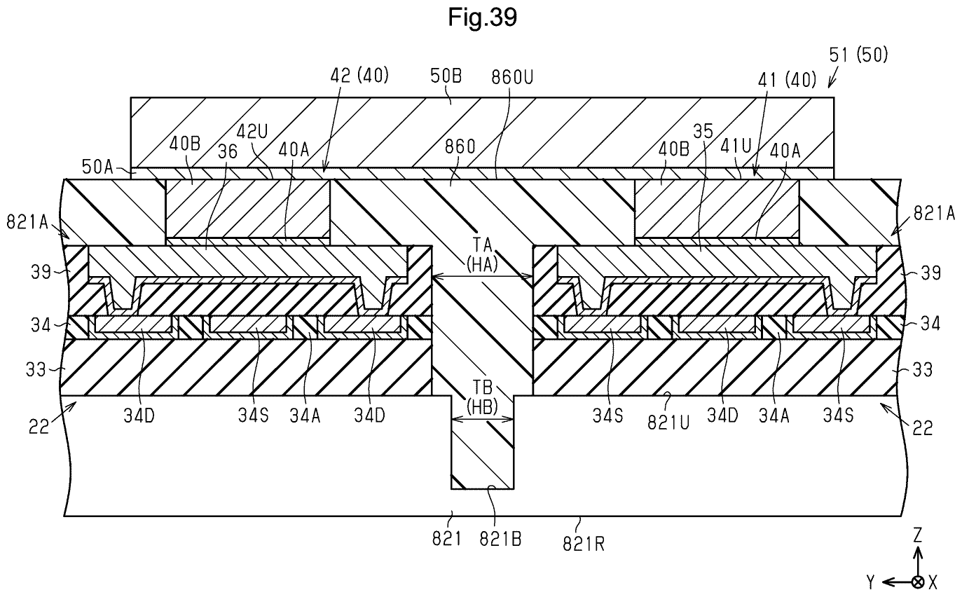

Subsequently, as shown in FIG. 39, the portion of the seed layer 50A exposed from the plating layer 50B is removed. In the example of FIG. 39, the interconnect layer 51 is formed. As described above, the method for manufacturing the semiconductor device 10 includes forming the interconnect layer 51 on the upper surface 860U of the resin layer 860 to electrically connect the source post 41 and the drain post 42. The steps described above forms the external wiring layer 50.

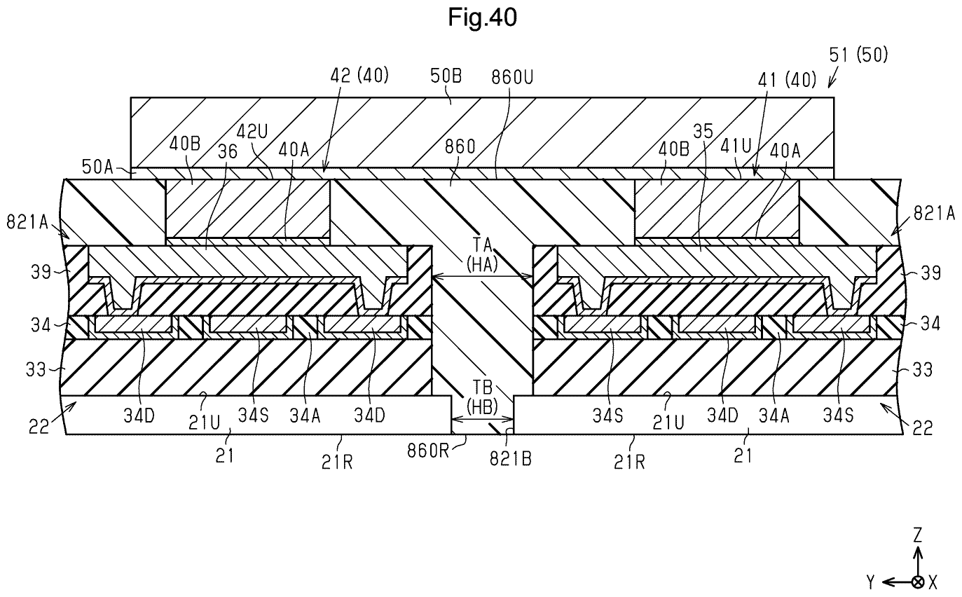

As shown in FIG. 40, the method for manufacturing the semiconductor device 10 includes polishing the wafer 821 from the wafer back surface 821R to expose the resin layer 860 in the groove 821B to electrically separate the wafer 821 for each chip formation region 821A and form the substrate 21 on which the GaN transistor 22 is formed.

In the example shown in FIG. 40, the portion (substrate encapsulation layer 62) of the resin layer 860 filling the groove 821B is also partially polished in the thickness-wise direction. As a result, the wafer 821 is divided for each chip formation region 821A. This forms the substrate 21. The resin layer 860 is arranged between adjacent ones of the substrates 21. The substrates 21 are insulated from each other for each chip formation region 821A. In addition, polishing marks are formed on the back surface 860R of the resin layer 860 and the substrate back surface 21R of the substrate 21. The back surface 860R of the resin layer 860 is flush with the substrate back surface 21R of the substrate 21. In other words, the substrate back surface 21R of the substrate 21 is exposed from the back surface 860R of the resin layer 860.

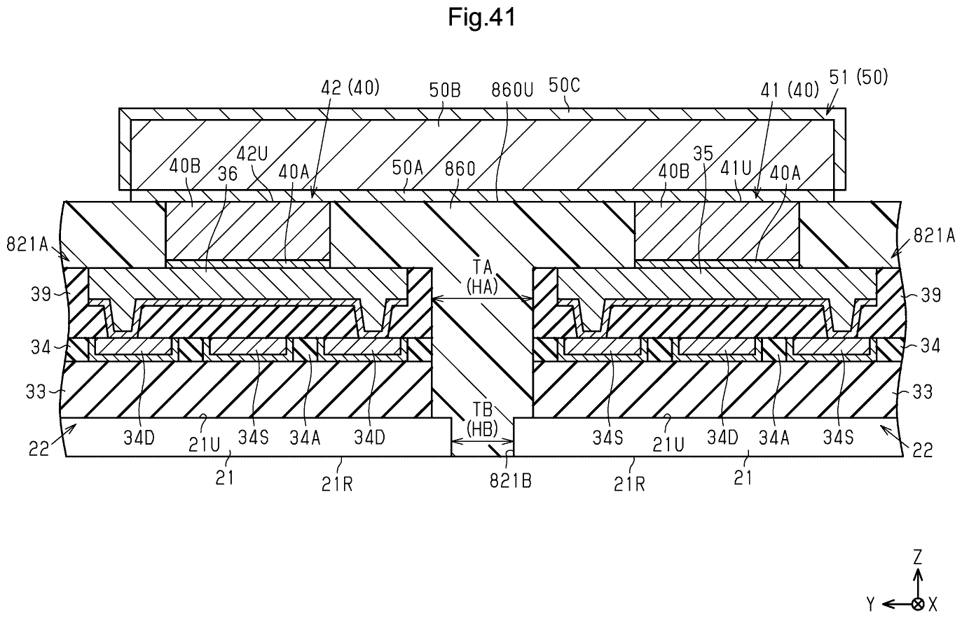

As shown in FIG. 41, the method for manufacturing the semiconductor device 10 includes forming a plating layer 50C on a surface of the external wiring layer 50. The plating layer 50C is formed by, for example, electroless plating. In the example shown in FIG. 41, the plating layer 50C is formed on the upper surface and the side surface of the interconnect layer 51. In an example, the plating layer 50C has a stack structure of nickel (Ni), palladium (Pd), and gold (Au), or a stack structure of Ni/Au.

As shown in FIG. 42, the method for manufacturing the semiconductor device 10 includes singulating the semiconductor device 10 by cutting the resin layer 860 so as to include multiple (in the example shown in FIG. 42, six) chip formation regions 821A in which the source post 41 and the drain post 42 are electrically connected by the interconnect layer 51. The singulating the semiconductor device 10 is performed after the forming the interconnect layer 51 (after the step shown in FIG. 41).

Referring to FIG. 42, multiple semiconductor devices 10 are formed on the wafer 821. In an example, a dicing blade is used to cut the resin layer 860 along cutting lines CL shown in FIG. 42. Thus, the semiconductor device 10 including the GaN units 20A to 20F (refer to FIG. 2) is singulated. The steps described above manufacture the semiconductor device 10.

### Operation

The operation of the semiconductor device 10 of the present embodiment will now be described.

For example, a wire and a clip are typical components that electrically connect the source pads 35 (source posts 41) of the GaN units 20A, 20C, and 20E to the drain pads 36 (drain posts 42) of the GaN units 20B, 20D, and 20F. For example, when the source pads 35 (source posts 41) of the GaN units 20A, 20C, and 20E are electrically connected to the drain pads 36 (drain posts 42) of the GaN units 20B, 20D, and 20F by wires, the wires are formed in an arched shape. This imposes limitations on decrease in the distance from the encapsulation front surface 60U of the first encapsulation resin 60 to the peaks of the wires in the Z-direction. The same issue applies to the use of clips.

In the semiconductor device 10 of the present embodiment, the interconnect layer 51 is arranged on the encapsulation front surface 60U of the first encapsulation resin 60 to electrically connect the source pads 35 (source posts 41) of the GaN units 20A, 20C, and 20E to the drain pads 36 (drain posts 42) of the GaN units 20B, 20D, and 20F. The interconnect layer 51 is plate-shaped and is in contact with the encapsulation front surface 60U. In other words, the interconnect layer 51 is not spaced apart from the encapsulation front surface 60U in the Z-direction. Thus, the distance from the encapsulation front surface 60U to the upper surface of the interconnect layer 51 in the Z-direction is less than the distance from the encapsulation front surface 60U to the peaks of the wires in the Z-direction. In addition, the interconnect layer 51 may be smaller in thickness than the clip. Therefore, the height of the semiconductor device 10 is reduced as compared to a structure in which the source pads 35 (source posts 41) of the GaN units 20A, 20C, and 20E are electrically connected to the drain pads 36 (drain posts 42) of the GaN units 20B, 20D, and 20F by, for example, wires, clips, or the like.

As the chip formation regions 821A are located closer to each other in the wafer 821, the GaN transistors 22 in the chip formation regions 821A have smaller variations in characteristics (gate threshold voltage, drain-source current). In the present embodiment, in the method for manufacturing the semiconductor device 10, the GaN units 20A to 20F are formed in the chip formation regions 821A located adjacent to each other in the wafer 821. This reduces variations in the characteristics of the GaN transistors 22 of the GaN units 20A to 20F in the semiconductor device 10.

In a structure in which the GaN units 20A to 20F are individually encapsulated by the first encapsulation resin, that is, six semiconductor devices corresponding to the GaN units 20A to 20F are mounted on the support substrate 110, the distances between adjacent ones of the semiconductor devices need to be increased in consideration of variations in the mounting of chips performed by a mounter.

In the present embodiment, after the resin layer 860 is formed on the wafer 821, the wafer 821 is polished from the wafer back surface 821R. As a result, the substrates 21 are separated for each of the GaN units 20A to 20F by the groove 821B formed in the wafer 821. That is, the GaN units 20A to 20F remain aligned at the wafer level. This eliminates the need to consider variations in the mounting of chips by a mounter, thereby reducing the area of a substrate on which the semiconductor device 10 of the present embodiment is mounted as compared to the area of a substrate on which six semiconductor devices are individually mounted. Accordingly, the semiconductor module 100 is miniaturized. The semiconductor device 10 including the six GaN units 20A to 20F is mounted in a shorter time than when six semiconductor devices corresponding to the GaN units 20A to 20F are individually mounted.

The semiconductor device 10 of the present embodiment includes the six GaN units 20A to 20F. That is, the semiconductor device 10 is singulated by dicing for each six GaN units 20A to 20F. Thus, the distance DA between adjacent ones of the GaN units 20A to 20F is decreased as compared to a structure in which the GaN units 20A to 20F are singulated as separate semiconductor devices. The semiconductor device 10 of the present embodiment is miniaturized as compared to a semiconductor device in which the GaN units 20A to 20F singulated as separate semiconductor devices are arranged.

### Advantages

The semiconductor device 10 and the semiconductor module 100 of the present embodiment obtain the following advantages.

(1) The semiconductor device 10 includes a first encapsulation resin 60 having an encapsulation front surface 60U and an encapsulation back surface 60R that face in opposite directions, and multiple GaN units 20A and 20B arranged in the first encapsulation resin 60 separately from each other in a first direction (Y-direction) orthogonal to the thickness-wise direction (Z-direction) of the first encapsulation resin 60. Each of the GaN units 20A and 20B includes a substrate 21 having a substrate front surface 21U facing the same direction as the encapsulation front surface 60U and a substrate back surface 21R facing the same direction as the encapsulation back surface 60R, a GaN transistor 22 arranged on the substrate front surface 21U, and a post 40 arranged on a source pad 35, a drain pad 36, and a gate pad 37 of the GaN transistor 22 and exposed from the first encapsulation resin 60. The post 40 includes a source post 41 formed on the source pad 35 in one of two adjacent ones of the GaN units 20A and 20B in the first direction (Y-direction), and a drain post 42 formed on the drain pad 36 in the other one of the two adjacent ones of the GaN units 20A and 20B in the first direction (Y-direction). The semiconductor device 10 includes an interconnect layer 51 arranged on the encapsulation front surface 60U and electrically connecting the source post 41 and the drain post 42.

Thus, the structure in which the source post 41 and the drain post 42 are electrically connected by the interconnect layer 51 is smaller in the Z-direction than a structure in which the source post 41 and the drain post 42 are electrically connected by a wire, a clip, or the like. Accordingly, the height of the semiconductor device 10 is reduced as compared to the structure in which the source post 41 and the drain post 42 are electrically connected by a wire, a clip, or the like.

(2) The substrate back surface 21R of each substrate 21 is exposed from the encapsulation back surface 60R of the first encapsulation resin 60.

With this structure, heat from the GaN transistor 22 is readily dissipated from the substrate 21 to the outside of the semiconductor device 10 through the substrate back surface 21R. This improves the heat dissipation property of the semiconductor device 10.

(3) The substrate back surfaces 21R are flush with the encapsulation back surface 60R.

For example, when the semiconductor device 10 is mounted on the support substrate 110, this structure limits inclination of the semiconductor device 10 with respect to the support substrate front surface 110U of the support substrate 110, which would be caused by a difference in position in the Z-direction between the substrate back surface 21R and the encapsulation back surface 60R.

(4) Polishing marks are formed on the substrate back surfaces 21R and the encapsulation back surface 60R.

With this structure, for example, the second encapsulation resin 180 located between the encapsulation back surfaces 60R of the first encapsulation resins 60 and the support substrate front surface 110U of the support substrate 110 enters the polishing marks in the semiconductor module 100. This improves the adhesion between the first encapsulation resin 60 and the second encapsulation resin 180.

(5) The upper surface 41U of the source post 41, the upper surface 42U of the drain post 42, and the encapsulation front surface 60U are flush with each other.

This structure allows the interconnect layer 51 to be readily formed on the encapsulation front surface 60U and electrically connect the source post 41 and the drain post 42.

(6) Each GaN transistor 22 includes a drain electrode 30, a source electrode 29, a gate electrode 28, and a wiring layer 34 arranged on the substrate 21 to electrically connect the drain electrode 30, the source electrode 29, and the gate electrode 28 to the drain pad 36, the source pad 35, and the gate pad 37, respectively. The first encapsulation resin 60 covers the wiring layers 34 and is arranged between the wiring layers 34 in each two of the GaN units 20A and 20B located adjacent to each other in the first direction (Y-direction).

With this structure, the insulating properties of the GaN transistors 22 of the GaN units 20A and 20B are improved by the first encapsulation resin 60 arranged between the wiring layers 34 of the GaN units 20A and 20B.

(7) The method for manufacturing the semiconductor device 10 includes preparing a wafer 821 having a wafer front surface 821U and a wafer back surface 821R and including multiple chip formation regions 821A in which GaN transistors 22 are formed at a side of the wafer front surface 821U, forming a groove 821A between adjacent ones of the chip formation regions 821A, forming a post 40 on each of the source pad 35, the drain pad 36, and the gate pad 37 of each GaN transistor 22, forming a resin layer 860 filling the groove 821A and exposing the upper surfaces of the posts 40 on the wafer 821, and polishing the wafer 821 from the wafer back surface 821R to expose the resin layer 860 in the groove 821B to electrically separate the wafer 821 for each of the chip formation regions 821A and form a substrate 21 on which the GaN transistor 22 is formed. The post 40 includes a source post 41 and a drain post 42. The source post 41 is formed on the source pad 35 of one of the chip formation regions 821A located adjacent to each other, and forming the drain post 42 on the drain pad 36 of the other one of the chip formation regions 821A. The method for manufacturing the semiconductor device 10 includes forming the interconnect layer 51, which electrically connects the source post 41 and the drain post 42 to each other, on the upper surface 860U of the resin layer 860.

Thus, the structure in which the source post 41 and the drain post 42 are electrically connected by the interconnect layer 51 is smaller in the Z-direction than a structure in which the source post 41 and the drain post 42 are electrically connected by a wire, a clip, or the like. Accordingly, the height of the semiconductor device 10 is reduced as compared to the structure in which the source post 41 and the drain post 42 are electrically connected by a wire, a clip, or the like.

(8) The method for manufacturing the semiconductor device 10 further includes, subsequent to forming the interconnect layer 51, singulating the semiconductor device 10 by cutting the resin layer 860 so as to include multiple chip formation regions 821A in which the drain post 42 and the source post 41 are connected to each other by the interconnect layer 51.

In this structure, the semiconductor device 10 includes the chip formation regions 821A adjacent to each other in the wafer 821. This allows for manufacturing of the semiconductor device 10 that limits variations in the characteristics of the GaN transistors 22.

(9) The forming the resin layer 860 exposing the upper surface of the post 40 on the wafer 821 further includes forming the resin layer 860 to fill the groove 821B and the gap between adjacent ones of the chip formation regions 821A and to cover the post 40, and polishing the upper surface 860U of the resin layer 860 and the upper surface of the post 40 to expose the post 40 from the upper surface 860U of the resin layer 860.

With this structure, the resin layer 860 and the post 40, which are formed on the source pad 35, the drain pad 36, and the gate pad 37, are reduced in thickness. This decreases the height of the semiconductor device 10.

(10) The semiconductor module 100 includes a first interconnect 121 arranged on the support substrate 110 to electrically connect the drive chip 160 and the semiconductor device 10, and a second interconnect 122 arranged on the support substrate 110 to electrically connect the control chip 170 and the drive chip 160.

With this structure, the semiconductor device 10 and the drive chip 160 are electrically connected to each other, and the control chip 170 and the drive chip 160 are electrically connected to each other inside the semiconductor module 100. Thus, the conductive path between the semiconductor device 10 and the drive chip 160 is shortened as compared to a structure in which the semiconductor device 10 and the drive chip 160 are electrically connected to each other outside the semiconductor module 100. In addition, the conductive path between the drive chip 160 and the control chip 170 is shortened as compared to the structure in which the drive chip 160 and the control chip 170 are electrically connected to each other outside the semiconductor module 100.

### MODIFIED EXAMPLES

The embodiment described above may be modified as follows. The modified examples described below may be combined with one another as long as there is no technical inconsistency.

### Modified Examples of Semiconductor Device

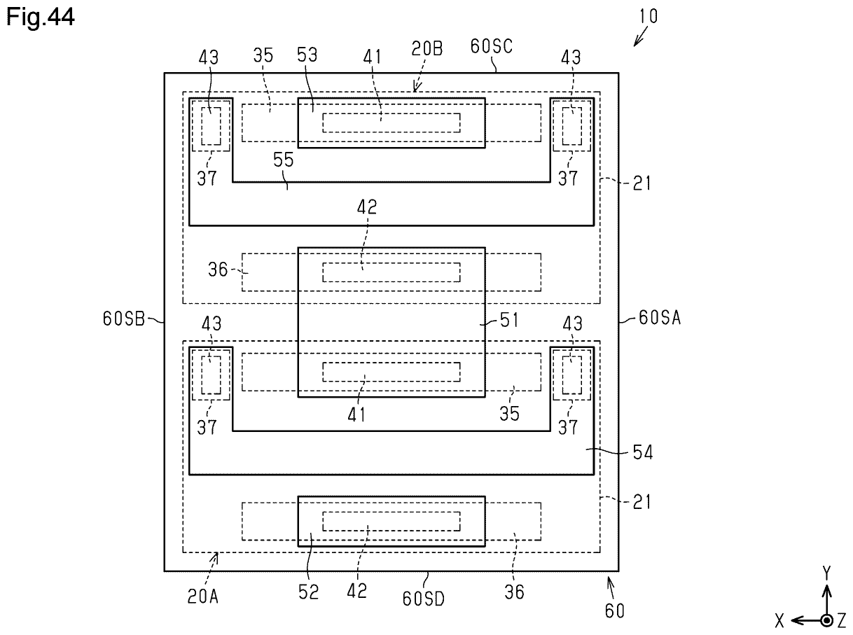

In the semiconductor device 10, the number of GaN units may be changed in any manner. In an example, as shown in FIG. 44, the semiconductor device 10 may include two GaN units. For the sake of convenience, the two GaN units are referred to as “GaN unit 20A” and “GaN unit 20B”. The GaN unit 20A and the GaN unit 20B are arranged adjacent to each other in the Y-direction (first direction).

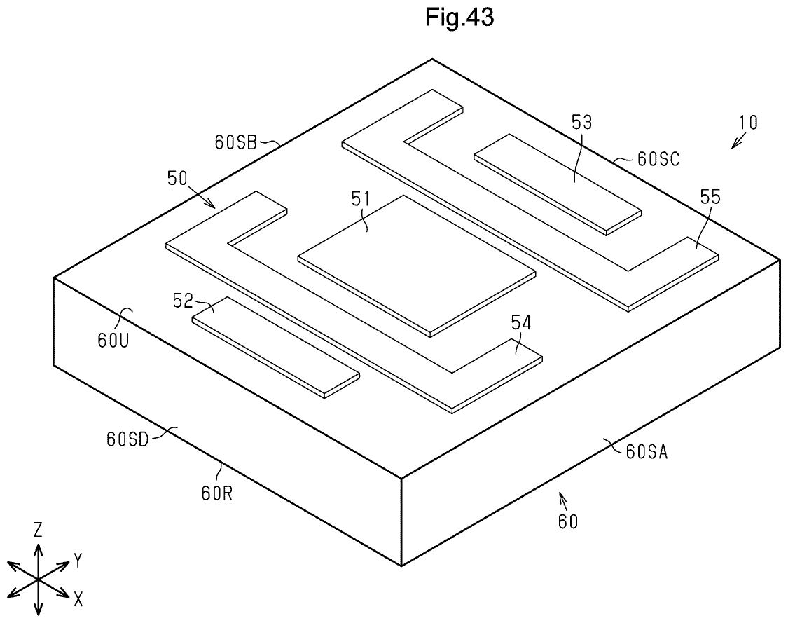

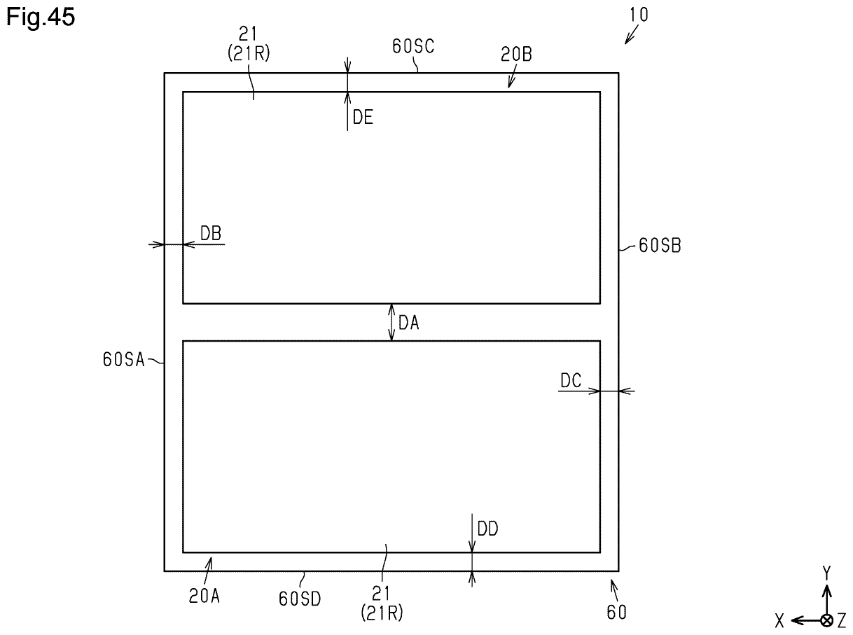

As shown in FIGS. 43 to 45, the structure of the GaN units 20A and 20B in this modified example is the same as the structure of the GaN units 20A and 20B in the embodiment described above. As shown in FIGS. 43 and 44, the first encapsulation resin 60 is rectangular so that the long sides extend in the Y-direction and the short sides extend in the X-direction. As shown in FIG. 45, the substrate back surface 21R of the substrate 21 of the GaN unit 20A and the substrate back surface 21R of the substrate 21 of the GaN unit 20B are exposed from the encapsulation back surface 60R of the first encapsulation resin 60. The substrate back surface 21R of the substrate 21 of the GaN unit 20A and the substrate back surface 21R of the substrate 21 of the GaN unit 20B are aligned with each other in the X-direction and spaced apart from each other in the Y-direction. In an example, the substrate back surface 21R of the substrate 21 of the GaN unit 20A, the substrate back surface 21R of the substrate 21 of the GaN unit 20B, and the encapsulation back surface 60R are flush with each other. In an example, the substrate back surface 21R of the substrate 21 of the GaN unit 20A, the substrate back surface 21R of the substrate 21 of the GaN unit 20B, and the encapsulation back surface 60R are polished so that the substrate back surface 21R of the substrate 21 of the GaN unit 20A, the substrate back surface 21R of the substrate 21 of the GaN unit 20B, and the encapsulation back surface 60R are flush with each other. As a result, polishing marks are formed on the substrate back surface 21R of the substrate 21 of the GaN unit 20A, the substrate back surface 21R of the substrate 21 of the GaN unit 20B, and the encapsulation back surface 60R.

The semiconductor device 10 may include four GaN units. In this case, the four GaN units may be arranged so that two sets of two GaN units are spaced apart from each other in the X-direction (second direction), and, in each set, the two GaN units are located adjacent to each other in the Y-direction (first direction). The semiconductor device 10 may include eight or more GaN units.

In the semiconductor device 10, the substrate back surface 21R of the substrate 21 of at least one of the GaN units 20A to 20F may be configured not to be flush with the encapsulation back surface 60R of the first encapsulation resin 60.

In the semiconductor device 10, the substrate back surface 21R of the substrate 21 of at least one of the GaN units 20A to 20F may be configured not to be exposed from the first encapsulation resin 60. In other words, the first encapsulation resin 60 may cover the substrate back surface 21R of the substrate 21 of at least one of the GaN units 20A to 20F.

In the method for manufacturing the semiconductor device 10, formation of polishing marks may be omitted from at least one of the substrate back surface 21R of the substrate 21 in each of the GaN units 20A to 20F and the encapsulation back surface 60R of the first encapsulation resin 60.

The upper surface 41U of the source post 41, the upper surface 42U of the drain post 42, and the encapsulation front surface 60U of the first encapsulation resin 60 may be configured not to be flush with each other. For example, the upper surface 41U of the source post 41 and the upper surface 42U of the drain post 42 may protrude from the encapsulation front surface 60U.

In the first encapsulation resin 60, the dimension HA of the wiring encapsulation layer 61 may be equal to the dimension HB of the substrate encapsulation layer 62. Moreover, the dimension HA of the wiring encapsulation layer 61 may be less than the dimension HB of the substrate encapsulation layer 62.

The first encapsulation resin 60 may be arranged so as not to be arranged between the wiring layers 34 of two adjacent ones of the GaN units in the GaN units 20A to 20F.

The first encapsulation resin 60 may be configured not to cover at least one of the drain pad 36, the source pad 35, and the gate pad 37.

The nitride semiconductor is not limited to GaN. Typical examples of the nitride semiconductor, other than GaN, include aluminum nitride and indium nitride (InN). A typical expression may be AlₓIn_{y}Ga_{1-x-y}N (0≤x≤1, 0≤y≤1, 0≤x+y≤1).

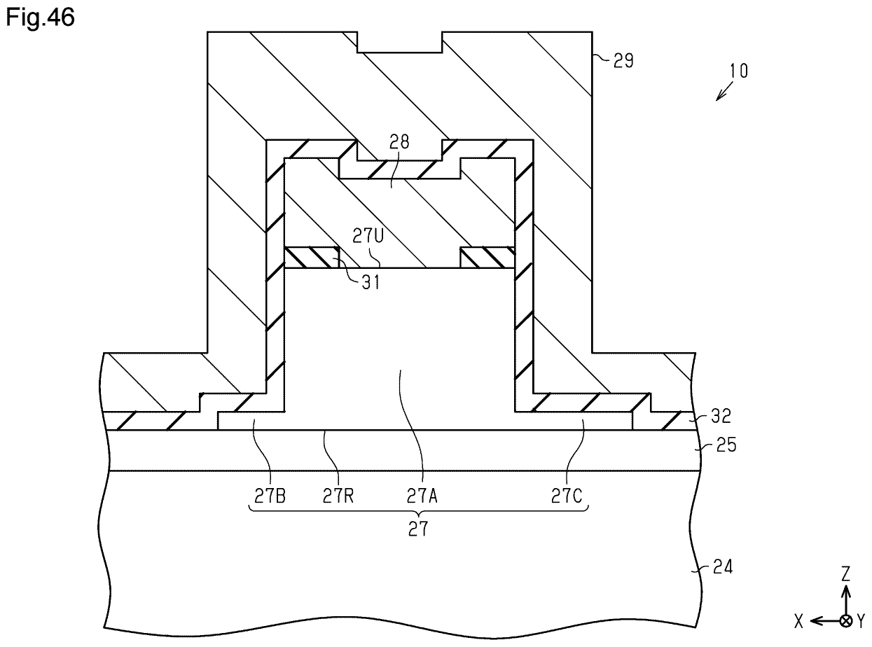

The structure of the gate layer 27 may be changed in any manner. In an example, as shown in FIG. 46, the gate layer 27 includes a gate layer body 27A, a source extension 27B extending from the gate layer body 27A toward the source contact portion 29A (refer to FIG. 5) of the source electrode 29, and a drain extension 27C extending from the gate layer body 27A toward the drain electrode 30 (refer to FIG. 5). The gate layer body 27A includes the upper surface 27U of the gate layer 27. The lower surface 27R of the gate layer 27 is defined by the lower surface of the gate layer body 27A, the lower surface of the source extension 27B, and the lower surface of the drain extension 27C. Therefore, in the gate layer 27, the lower surface 27R has a larger area than the upper surface 27U.

The gate layer body 27A is located between the source extension 27B and the drain extension 27C and is formed integrally with the source extension 27B and the drain extension 27C. The gate layer body 27A corresponds to a relatively thick portion of the gate layer 27.

The source extension 27B and the drain extension 27C are smaller in thickness than the gate layer body 27A. The thickness of each of the source extension 27B and the drain extension 27C may be less than or equal to half the thicknesses of the gate layer body 27A. In plan view, the drain extension 27C may extend outward from the gate layer body 27A longer than the source extension 27B does. That is, the drain extension 27C may have a larger dimension in the X-axis direction than the source extension 27B. The dimension of the source extension 27B in the X-axis direction may be, for example, in a range of 0.2 μm to 0.3 μm, inclusive. The dimension of the drain extension 27C in the X-axis direction may be, for example, in a range of 0.2 μm to 0.6 μm, inclusive.

In the modified example shown in FIG. 46, one of the source extension 27B and the drain extension 27C may be omitted from the gate layer 27. When the gate layer 27 includes one of the source extension 27B and the drain extension 27C, local concentration of electric field in the gate layer 27 is limited.

In the semiconductor device 10, the number of gate pads 37 may be changed in any manner. In an example, the semiconductor device 10 may include a single gate pad 37.

In the semiconductor device 10, the source field plate portion 29B of the source electrode 29 may be arranged at a position separated from the second insulation film 32 in the Z-direction.

The first insulation film 31 may be omitted from the semiconductor device 10. In this case, for example, the gate electrode 28 may be arranged to be in contact with the entire surface of the gate layer 27. The gate electrode 28 may be arranged to have a smaller width-wise dimension than the gate layer 27.

The source post 41 of the GaN unit 20A and the drain post 42 of the GaN unit 20B may be electrically connected by, for example, a wire or a clip. The source post 41 of the GaN unit 20C and the drain post 42 of the GaN unit 20D may be electrically connected by, for example, a wire or a clip. The source post 41 of the GaN unit 20E and the drain post 42 of the GaN unit 20F may be electrically connected by, for example, a wire or a clip.

### Modified Example of the Method for Manufacturing the Semiconductor Device

Prior to formation of the interconnect layer 51, the semiconductor device 10 may be singulated by cutting the resin layer 860 so as to include multiple chip formation regions 821A.

The resin layer 860 may be formed by transfer molding or compression molding so that the upper surface of the post 40 is exposed from the resin layer 860. In this case, the step of polishing the upper surface 860U of the resin layer 860 and the upper surface of the post 40 is omitted.

### Modified Examples of the Semiconductor Module

The semiconductor device 10 and the drive chip 160 may be electrically connected to each other outside the semiconductor module 100.

The drive chip 160 and the control chip 170 may be electrically connected to each other outside the semiconductor module 100.

The control chip 170 may be omitted from the semiconductor module 100. In this case, instead of the second interconnect 122 and the control interconnect 124, third interconnects are arranged on the support substrate 110 to individually electrically connect the drive chip 160 to the control terminals 150.

The boot terminals 146 to 148 may be omitted from the semiconductor module 100. In this case, the boot interconnect 125 may also be omitted.

The second encapsulation resin 180 may be omitted from the semiconductor module 100.

One or more of the various examples described in this specification may be combined as long as there is no technical contradiction.

In this specification, “at least one of A and B” should be understood to mean “only A, or only B, or both A and B.”

In the present disclosure, the term “on” includes the meaning of “above” in addition to the meaning of “on” unless otherwise clearly indicated in the context. Accordingly, for example, the expression of “first element mounted on second element” may mean that the first element is placed directly on the second element in one embodiment and mean that the first element is placed above the second element without contacting the second element in another embodiment. In other words, the term “on” does not exclude a structure in which another component is formed between the first component and the second component.

The Z-axis direction as referred to in the present disclosure does not necessarily have to be the vertical direction and does not necessarily have to fully conform to the vertical direction. Accordingly, in the structures of the present disclosure, “up” and “down” in the Z-axis direction as referred to in this specification are not limited to “up” and “down” in the vertical direction. For example, the X-axis direction may be the vertical direction. Alternatively, the Y-axis direction may be the vertical direction.

### CLAUSES

Technical concepts that can be understood from the above embodiment and modified examples will now be described. The reference signs of the components in the embodiments are given to the corresponding components in clauses with parentheses. The reference signs are used as examples to facilitate understanding, and the components in each clause are not limited to those components given with the reference signs.

### [Clause A1]

A semiconductor device (10), including:
a first encapsulation resin (60) including an encapsulation front surface (60U) and an encapsulation back surface (60R) that face in opposite directions;
multiple GaN units (20A, 20B) arranged in the first encapsulation resin (60) separately from each other in a first direction (Y-direction) orthogonal to a thickness-wise direction (Z-direction) of the first encapsulation resin (60); and
an interconnect layer (51) arranged on the encapsulation front surface (60U), where
each of the GaN units (20A, 20B) includes:
   a substrate (21) including a substrate front surface (21U) facing the same direction as the encapsulation front surface (60U) and a substrate back surface (21R) facing the same direction as the encapsulation back surface (60R);
   a GaN transistor (22) arranged at a substrate front surface side of the substrate (21); and
   a post (40) arranged on a source pad (35), a drain pad (36), and a gate pad (37) of the GaN transistor (22) and exposed from the first encapsulation resin (60),
the post (40) includes:
   a source post (41) formed on the source pad (35) in one (20A) of two adjacent ones of the GaN units (20A, 20B) in the first direction (Y-direction); and
   a drain post (42) formed on the drain pad (36) in the other one (20B) of the two adjacent ones of the GaN units (20A, 20B) in the first direction (Y-direction), and
the interconnect layer (51) electrically connects the source post (41) and the drain post (42).

### [Clause A2]

The semiconductor device according to clause A1, where the substrate back surfaces (21R) are exposed from the encapsulation back surface (60R).

### [Clause A3]

The semiconductor device according to clause A2, where the substrate back surfaces (21R) are flush with the encapsulation back surface (60R).

### [Clause A4]

The semiconductor device according to clause A3, where a polishing mark is formed on the substrate back surfaces (21R) and the encapsulation back surface (60R).

### [Clause A5]

The semiconductor device according to any one of clauses A1 to A3, where an upper surface (41U) of the source post (41), an upper surface (42U) of the drain post (42), and the encapsulation front surface (60U) are flush with each other.

### [Clause A6]

The semiconductor device according to any one of clauses A1 to A4, where
each of the GaN units (20A, 20B) includes
   a drain electrode (30),
   a source electrode (29),
   a gate electrode (28), and
   a wiring layer (34) arranged on the substrate (21) to electrically connect the drain electrode (30), the source electrode (29), and the gate electrode (28) to the drain pad (36), the source pad (35), and the gate pad (37), respectively, and
the first encapsulation resin (60) covers the wiring layers (34) and is arranged between the wiring layers (34) of each two of the GaN units (20A, 20B) located adjacent to each other in the first direction (Y-direction).

### [Clause A7]

The semiconductor device according to clause A6, where
the first encapsulation resin (60) includes
   a wiring encapsulation layer (61) arranged between two of the wiring layers (34) located adjacent to each other in the first direction (Y-direction), and
   a substrate encapsulation layer (62) arranged between two of the substrates (21) located adjacent to each other in the first direction (Y-direction), and
a dimension (HA) of the wiring encapsulation layer (61) in the first direction (Y-direction) is greater than a dimension (HB) of the substrate encapsulation layer (62) in the first direction (Y-direction).

### [Clause A8]

The semiconductor device according to any one of clauses A1 to A7, where the drain pad (36), the source pad (35), and the gate pad (37) of each of the GaN units (20A, 20B) are covered by the first encapsulation resin (60).

### [Clause A9]

The semiconductor device according to any one of clauses A1 to A8, where the GaN units (20A, 20B) include two of the GaN units (20A, 20B) located adjacent to each other in the first direction (Y-direction).

### [Clause A10]

The semiconductor device according to any one of clauses A1 to A8, where
a second direction (X-direction) refers to a direction orthogonal to the thickness-wise direction (Z-direction) of the first encapsulation resin (60) and the first direction (Y-direction), and
the GaN units (20A, 20B) include six of the GaN units (20A to 20F) arranged so that three sets of two of the GaN units (20A, 20B/20C, 20D/20E, 20F) are spaced apart from each other in the second direction (X-direction) and, in each set, the two of the GaN units (20A, 20B/20C, 20D/20E, 20F) are located adjacent to each other in the first direction (Y-direction).

### [Clause A11]

A semiconductor module (100), including:
a support substrate (110);
the semiconductor device (10) according to any one of clauses A1 to A10 arranged on the support substrate (110);
a drive chip (160) arranged on the support substrate (110) and electrically connected to the semiconductor device (10);
a control chip (170) arranged on the support substrate (110) and electrically connected to the drive chip (160); and
a second encapsulation resin (180) encapsulating the semiconductor device (10), the control chip (170), and the drive chip (160).

### [Clause A12]

The semiconductor module according to clause A11, further including:
a first interconnect (121) arranged on the support substrate (110) to electrically connect to the drive chip (160) and the semiconductor device (10); and
a second interconnect (122) arranged on the support substrate (110) to electrically connect the control chip (170) and the drive chip (160).

### [Clause A13]

The semiconductor module according to clause A12, where the support substrate (110) includes a support substrate front surface (110U) and a support substrate back surface (110R) that face in opposite directions, the semiconductor module, further including:
a drive terminal (141, 142) and a control terminal (150) arranged on the support substrate back surface (110R),
a drive interconnect (123) arranged on the support substrate front surface (110U) and electrically connected to the semiconductor device (10),
a control interconnect (124) arranged on the support substrate front surface (110U) and electrically connected to the control chip (170),
a drive through interconnect (131) extending through the support substrate (110) in a thickness-wise direction (Z-direction) of the support substrate (110) to electrically connect the drive terminal (141, 142) and the drive interconnect (123), and
a control through interconnect (132) extending through the support substrate (110) in the thickness-wise direction (Z-direction) of the support substrate (110) to electrically connect the control terminal (150) and the control interconnect (124).

### [Clause A14]

The semiconductor module according to clause A13, further including:
a boot terminal (146 to 148) arranged on the support substrate back surface (110R);
a boot interconnect (125) arranged on the support substrate front surface (110U) and electrically connected to the drive chip (160); and
a boot through interconnect (133) extending through the support substrate (110) in the thickness-wise direction (Z-direction) of the support substrate (110) and electrically connecting the boot terminal (146 to 148) and the boot interconnect (125).

### [Clause A15]

A method for manufacturing a semiconductor device (10), the method including:
preparing a wafer (821) including a wafer front surface (821U) and a wafer back surface (821R) and including chip formation regions (821A) in which GaN transistors (22) are arranged at a wafer front surface side of the wafer (821);
forming a groove (821B) between adjacent ones of the chip formation regions (821A);
forming a post (40) on each of a source pad (35), a drain pad (36), and a gate pad (37) of each of the GaN transistors (22);
forming a resin layer (860) filling the groove (821B) and exposing an upper surface of the post (40) on the wafer (821);
polishing the wafer (821) from the wafer back surface (821R) to expose the resin layer (860) in the groove (821B), thereby electrically separating the wafer (821) to form a substrate for each of the chip formation regions (821A) so that at least one of the GaN transistors (22) is formed on each substrate;
the post (40) including a source post (41) and a drain post (42), forming the source post (41) on the source pad (35) in one of two adjacent ones of the chip formation regions (821A) and forming the drain post (42) on the drain pad (36) in the other one of the two adjacent ones of the chip formation regions (821A); and
forming an interconnect layer (51) on an upper surface (860U) of the resin layer (860) to electrically connect the source post (41) and the drain post (42).

### [Clause A16]

The method according to clause A15, where
each of the GaN transistors (22) includes
   a source electrode (29),
   a drain electrode (30),
   a gate electrode (28), and
   a wiring layer (834) electrically connected to each of the source electrode (29), the drain electrode (30), and the gate electrode (28), and
the forming a groove (821B) between adjacent ones of the chip formation regions (821A) includes forming the groove (821B) having a width-wise dimension that is less than a distance between the wiring layers (834) of the adjacent ones of the chip formation regions (821A).

### [Clause A17]

The method according to clause A15 or A16, where the forming a resin layer (860) exposing an upper surface of the post (40) on the wafer (821) further includes:
forming the resin layer (860) to fill the groove (821B) and a gap between adjacent ones of the chip formation regions (821A) and cover the post (40), and
polishing the upper surface (860U) of the resin layer (860) and the upper surface of the post (40) to expose the post (40) from the upper surface (860U) of the resin layer (860).

### [Clause A18]

The method according to any one of clauses A15 to A17, further including:
subsequent to forming the interconnect layer (51), singulating a semiconductor device (10) by cutting the resin layer (860) so as to include multiple chip formation regions (821A) in which the drain post (42) and the source post (41) are connected by the interconnect layer (51).

### [Clause A19]

A semiconductor module (100), including:
a support substrate (110);
the semiconductor device (10) according to any one of clauses A1 to A10 arranged on the support substrate (110); and
a drive chip (160) arranged on the support substrate (110) and electrically connected to the semiconductor device (10).

### [Clause A20]

The semiconductor module according to clause A19, further including:
a second encapsulation resin (180) encapsulating the semiconductor device (10) and the drive chip (160).

### [Clause A21]

The semiconductor module according to clause A20, further including:
a control chip (170) arranged on the support substrate (110) and electrically connected to the drive chip (160),
where the second encapsulation resin (180) encapsulates the semiconductor device (10), the control chip (170), and the drive chip (160).

### [Clause B1]

A method for manufacturing a semiconductor device, the method including:
preparing a wafer (821) including a wafer front surface (821U) and a wafer back surface (821R) and including chip formation regions (821A) in which GaN transistors (22) are arranged at a wafer front surface side of the wafer (821);
forming a groove (821B) between adjacent ones of the chip formation regions (821A),
forming a post (40) on each of a source pad (35), a drain pad (36), and a gate pad (37) of each of the GaN transistors (22);
forming a resin layer (860) on the wafer (821) so that the resin layer (860) fills the groove (821B) and exposes an upper surface of the post (40); and
polishing the wafer (821) from the wafer back surface (821R) to expose the resin layer (860) in the groove (821B), thereby electrically separating the wafer (821) to form a substrate for each of the chip formation regions (821A) so that at least one of the GaN transistors (22) is formed on each substrate.

### Technical Problem to be Solved by Clause B1

When multiple switching elements are mounted on a substrate using a mounter, variations in the mounting of the switching elements performed by the mounter need to be considered. Hence, the distances between adjacent ones of the switching elements need to be increased. Therefore, there is room for improvement in miniaturization of the semiconductor device.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a first encapsulation resin including an encapsulation front surface and an encapsulation back surface that face in opposite directions;
multiple GaN units arranged in the first encapsulation resin separately from each other in a first direction orthogonal to a thickness-wise direction of the first encapsulation resin; and
an interconnect layer arranged on the encapsulation front surface, wherein
each of the GaN units includes:
a substrate including a substrate front surface facing the same direction as the encapsulation front surface and a substrate back surface facing the same direction as the encapsulation back surface;
a GaN transistor arranged at a substrate front surface side of the substrate; and
a post arranged on a source pad, a drain pad, and a gate pad of the GaN transistor and exposed from the first encapsulation resin,
the post includes:
a source post formed on the source pad in one of two adjacent ones of the GaN units in the first direction; and
a drain post formed on the drain pad in the other one of the two adjacent ones of the GaN units in the first direction, and
the interconnect layer electrically connects the source post and the drain post.

2. The semiconductor device according to claim 1, wherein the substrate back surfaces are exposed from the encapsulation back surface.

3. The semiconductor device according to claim 2, wherein the substrate back surfaces are flush with the encapsulation back surface.

4. The semiconductor device according to claim 3, wherein a polishing mark is formed on the substrate back surfaces and the encapsulation back surface.

5. The semiconductor device according to claim 1, wherein an upper surface of the source post, an upper surface of the drain post, and the encapsulation front surface are flush with each other.

6. The semiconductor device according to claim 1, wherein
each of the GaN units includes
a drain electrode,
a source electrode,
a gate electrode, and
a wiring layer arranged on the substrate to electrically connect the drain electrode, the source electrode, and the gate electrode to the drain pad, the source pad, and the gate pad, respectively, and
the first encapsulation resin covers the wiring layers and is arranged between the wiring layers of each two of the GaN units located adjacent to each other in the first direction.

7. The semiconductor device according to claim 6, wherein
the first encapsulation resin includes
a wiring encapsulation layer arranged between two of the wiring layers located adjacent to each other in the first direction, and
a substrate encapsulation layer arranged between two of the substrates located adjacent to each other in the first direction, and
a dimension of the wiring encapsulation layer in the first direction is greater than a dimension of the substrate encapsulation layer in the first direction.

8. The semiconductor device according to claim 1, wherein the drain pad, the source pad, and the gate pad of each of the GaN units are covered by the first encapsulation resin.

9. The semiconductor device according to claim 1, wherein the GaN units include two of the GaN units located adjacent to each other in the first direction.

10. The semiconductor device according to claim 1, wherein
a second direction refers to a direction orthogonal to the thickness-wise direction of the first encapsulation resin and the first direction, and
the GaN units include six of the GaN units arranged so that three sets of two of the GaN units are spaced apart from each other in the second direction and, in each set, the two of the GaN units are located adjacent to each other in the first direction.

11. A semiconductor module, comprising:
a support substrate;
the semiconductor device according to claim 1 arranged on the support substrate;
a drive chip arranged on the support substrate and electrically connected to the semiconductor device;
a control chip arranged on the support substrate and electrically connected to the drive chip; and
a second encapsulation resin encapsulating the semiconductor device, the control chip, and the drive chip.

12. The semiconductor module according to claim 11, further comprising:
a first interconnect arranged on the support substrate to electrically connect to the drive chip and the semiconductor device; and
a second interconnect arranged on the support substrate to electrically connect the control chip and the drive chip.

13. The semiconductor module according to claim 12, wherein the support substrate includes a support substrate front surface and a support substrate back surface that face in opposite directions, the semiconductor module, further comprising:
a drive terminal and a control terminal arranged on the support substrate back surface,
a drive interconnect arranged on the support substrate front surface and electrically connected to the semiconductor device,
a control interconnect arranged on the support substrate front surface and electrically connected to the control chip,
a drive through interconnect extending through the support substrate in a thickness-wise direction of the support substrate to electrically connect the drive terminal and the drive interconnect, and
a control through interconnect extending through the support substrate in the thickness-wise direction of the support substrate to electrically connect the control terminal and the control interconnect.

14. The semiconductor module according to claim 13, further comprising:
a boot terminal arranged on the support substrate back surface;
a boot interconnect arranged on the support substrate front surface and electrically connected to the drive chip; and
a boot through interconnect extending through the support substrate in the thickness-wise direction of the support substrate and electrically connecting the boot terminal and the boot interconnect.

15. A method for manufacturing a semiconductor device, the method comprising:
preparing a wafer including a wafer front surface and a wafer back surface and including chip formation regions in which GaN transistors are arranged at a wafer front surface side of the wafer;
forming a groove between adjacent ones of the chip formation regions;
forming a post on each of a source pad, a drain pad, and a gate pad of each of the GaN transistors;
forming a resin layer filling the groove and exposing an upper surface of the post on the wafer;
polishing the wafer from the wafer back surface to expose the resin layer in the groove, thereby electrically separating the wafer to form a substrate for each of the chip formation regions so that at least one of the GaN transistors is formed on each substrate;
the post including a source post and a drain post, forming the source post on the source pad in one of two adjacent ones of the chip formation regions and forming the drain post on the drain pad in the other one of the two adjacent ones of the chip formation regions; and
forming an interconnect layer on an upper surface of the resin layer to electrically connect the source post and the drain post.

16. The method according to claim 15, wherein
each of the GaN transistors includes
a source electrode,
a drain electrode,
a gate electrode, and
a wiring layer electrically connected to each of the source electrode, the drain electrode, and the gate electrode, and
the forming a groove between adjacent ones of the chip formation regions includes forming the groove having a width-wise dimension that is less than a distance between the wiring layers of the adjacent ones of the chip formation regions.

17. The method according to claim 15, wherein the forming a resin layer exposing an upper surface of the post on the wafer further includes:
forming the resin layer to fill the groove and a gap between adjacent ones of the chip formation regions and cover the post, and
polishing the upper surface of the resin layer and the upper surface of the post to expose the post from the upper surface of the resin layer.

18. The method according to claim 15, further comprising:
subsequent to forming the interconnect layer, singulating a semiconductor device by cutting the resin layer so as to include multiple chip formation regions in which the drain post and the source post are connected by the interconnect layer.
